(19) United States
(12) Patent Application Publication
(10) Pub. No.: US 2024/0170518 A1
(43) Pub. Date: May 23, 2024

(54) SOLID-STATE IMAGING DEVICE AND ELECTRONIC DEVICE

(71) Applicant: SONY SEMICONDUCTOR SOLUTIONS CORPORATION, KANAGAWA (JP)

(72) Inventor: YUSUKE TAKATSUKA, KANAGAWA (JP)

(21) Appl. No.: 18/549,906

(22) PCT Filed: Feb. 1, 2022
(86) PCT No.: PCT/JP2022/003769

§ 371 Date: Sep. 9, 2023

(30) Foreign Application Priority Data
Mar. 17, 2021 (JP) 2021-043102

(51) Int. Cl. H01L 27/146; H01L 23/00; H04N 25/77; H04N 25/79

(52) U.S. Cl. CPC H01L 27/14629; H01L 24/08; H01L 24/80; H01L 27/1463; H01L 27/14634; H01L 27/14636; H01L 27/14685; H01L 27/1469; H04N 25/77; H04N 25/79; H01L 2224/08145; H01L 2224/80895; H01L 2224/80896

(57) ABSTRACT

Provided are a solid-state imaging device and an electronic device that have high-sensitivity pixels while curbing deterioration in image quality. A solid-state imaging device according to one aspect of the present disclosure includes a first substrate including a first semiconductor substrate having a first surface and a second surface that is opposite to the first surface and on which light is incident, a plurality of pixels that is provided in the first semiconductor substrate and performs photoelectric conversion, and a first uneven structure that is provided on the first surface of the first semiconductor substrate and includes a material different from a material of the first semiconductor substrate, and a second substrate including a readout circuit that is bonded to the first substrate on the first surface side and outputs a pixel signal based on electric charge output from the plurality of pixels.

### TECHNICAL FIELD

The present disclosure relates to a solid-state imaging device and an electronic device.

### BACKGROUND ART

As a solid-state imaging device, a complementary metal oxide semiconductor (CMOS) image sensor and a charge coupled device (CCD) include single crystal silicon for a light detection element that performs photoelectric conversion. Although silicon has sensitivity to wavelengths of near infrared rays, it is necessary to increase the film thickness of the silicon layer in order to obtain high sensitivity. However, increasing the thickness of the silicon layer increases color mixing between adjacent pixels and causes deterioration in image quality.

### CITATION LIST

### Patent Document

Patent Document 1: Japanese Patent Application Laid-Open No. 2018-88532
Patent Document 2: Japanese Patent Application Laid-Open No. 2020-88380
Patent Document 3: Japanese Patent Application Laid-Open No. 2020-47734
Patent Document 4: Japanese Patent Application Laid-Open No. 2020-80342

### SUMMARY OF THE INVENTION

### Problems to be Solved by the Invention

Provided are a solid-state imaging device and an electronic device that have high-sensitivity pixels while curbing deterioration in image quality.

### Solutions to Problems

A solid-state imaging device according to one aspect of the present disclosure includes a first substrate including a first semiconductor substrate having a first surface and a second surface that is opposite to the first surface and on which light is incident, a plurality of pixels that is provided in the first semiconductor substrate and performs photoelectric conversion, and a first uneven structure that is provided on the first surface side of the first semiconductor substrate and includes a material different from a material of the first semiconductor substrate, and a second substrate including a pixel transistor that is bonded to the first substrate on the first surface side and outputs a pixel signal based on electric charge output from the plurality of pixels.

The solid-state imaging device further includes a second uneven structure provided on the second surface side of the first semiconductor substrate and including a material different from a material of the first semiconductor substrate.

The pixel includes a photoelectric conversion element, a transfer transistor electrically connected to the photoelectric conversion element, and a floating diffusion that temporarily holds electric charge output from the photoelectric conversion element via the transfer transistor, and the pixel transistor includes an amplification transistor that generates, as the pixel signal, a voltage signal according to electric charge held in the floating diffusion, and a selection transistor that controls an output timing of the pixel signal from the amplification transistor.

The solid-state imaging device further includes an element isolation structure provided between the pixels adjacent to each other in the first semiconductor substrate.

The transfer transistor is arranged at substantially the same position in each of the plurality of pixels in plan view as viewed from an incident direction of the light.

The transfer transistor includes an embedded gate electrode embedded in the first semiconductor substrate.

A first insulating film provided on a part of a side surface of the embedded gate electrode is thinner in film thickness than a second insulating film provided on another part of the side surface of the gate electrode.

At least a part of the pixel transistor is provided below the element isolation structure.

At least a part of the pixel transistor overlaps the element isolation structure in plan view as viewed from an incident direction of the light.

A first wiring layer of the second substrate includes a plurality of first wirings extending in a first direction and arranged in a second direction orthogonal to the first direction in plan view as viewed from an incident direction of the light. The first or second uneven structure has a substantially triangular, substantially trapezoidal, or substantially rectangular shape in a cross section perpendicular to the first surface.

The first or second uneven structure has a shape of a substantially quadrangular pyramid, a substantially truncated cone, a substantially truncated pyramid, a substantial cylinder, or a substantial prism.

A plurality of the first or second uneven structures is arranged in a matrix in a first direction and a second direction orthogonal to the first direction in plan view as viewed from an incident direction of the light.

A plurality of the first or second uneven structures extends in a first direction, is arranged in a second direction orthogonal to the first direction, and is formed in a stripe shape in plan view as viewed from an incident direction of the light.

The first or second uneven structure has a cross shape extending in a first direction and a second direction orthogonal to the first direction in plan view as viewed from an incident direction of the light.

The solid-state imaging device further includes a reflection member provided between the first uneven structure and the second substrate.

The solid-state imaging device further includes an electrode plug provided between the first substrate and the second substrate.

The wiring of the first substrate and the wiring of the second substrate are bonded by bonding the first substrate and the second substrate.

The solid-state imaging device further includes a third substrate bonded to the second substrate and including a logic circuit that processes the pixel signal.

An electronic device according to one aspect of the present disclosure includes a solid-state imaging device including a first substrate including a first semiconductor substrate having a first surface and a second surface that is opposite to the first surface and on which light is incident, a plurality of pixels that is provided in the first semiconductor substrate and performs photoelectric conversion, and a first uneven structure that is provided on the first surface side of the first semiconductor substrate and includes a material different from a material of the first semiconductor substrate, and a second substrate including a pixel transistor that is bonded to the first substrate on the first surface side and outputs a pixel signal based on electric charge output from the plurality of pixels.

### BRIEF DESCRIPTION OF DRAWINGS

FIG. 1 is a schematic diagram illustrating a configuration example of an imaging device according to a first embodiment.

FIG. 2 is a circuit diagram illustrating an example of a pixel and a readout circuit.

FIG. 3 is a circuit diagram illustrating an example of a pixel and a readout circuit.

FIG. 4 is a circuit diagram illustrating an example of a pixel and a readout circuit.

FIG. 5 is a circuit diagram illustrating an example of a pixel and a readout circuit.

FIG. 6 is a diagram illustrating an example of a connection mode between a plurality of readout circuits and a plurality of vertical signal lines.

FIG. 7 is a diagram illustrating an example of a vertical cross-sectional configuration of the imaging device.

FIG. 8 is a plan view illustrating an example of a planar layout of a first uneven structure and a transfer transistor.

FIG. 9 is a plan view illustrating an example of a planar layout of a second uneven structure.

FIG. 10 is a cross-sectional view illustrating an example of a manufacturing method of the imaging device according to the first embodiment.

FIG. 11 is a cross-sectional view illustrating the example of a manufacturing method of the imaging device according to the first embodiment.

FIG. 12 is a cross-sectional view illustrating the example of a manufacturing method of the imaging device according to the first embodiment.

FIG. 13 is a cross-sectional view illustrating the example of a manufacturing method of the imaging device according to the first embodiment.

FIG. 14 is a cross-sectional view illustrating the example of a manufacturing method of the imaging device according to the first embodiment.

FIG. 15 is a cross-sectional view illustrating the example of a manufacturing method of the imaging device according to the first embodiment.

FIG. 16 is a schematic diagram illustrating a configuration example of an imaging device according to a second embodiment.

FIG. 17 is a plan view illustrating a configuration example of the imaging device according to the second embodiment.

FIG. 18 is a plan view illustrating a configuration example of the imaging device according to the second embodiment.

FIG. 19 is a cross-sectional view illustrating a configuration example of an imaging device according to a third embodiment.

FIG. 20 is a cross-sectional view illustrating a configuration of an imaging device according to a fourth embodiment.

FIG. 21 is a plan view illustrating an example of a planar layout of a first uneven structure and a transfer transistor according to Modification 1.

FIG. 22 is a plan view illustrating an example of a planar layout of a first uneven structure and a transfer transistor according to Modification 1.

FIG. 23 is a plan view illustrating an arrangement of first and second uneven structures, a transfer transistor, and a readout circuit according to Modification 2.

FIG. 24 is a plan view illustrating an arrangement of first and second uneven structures, a transfer transistor, and a readout circuit according to Modification 2.

FIG. 25 is a plan view illustrating a configuration example of a wiring layer of a second substrate according to Modification 3.

FIG. 26 is a plan view showing a configuration example of a wiring layer of a second substrate according to Modification 3.

FIG. 27 is a cross-sectional view illustrating a configuration example of an imaging device according to a fifth embodiment.

FIG. 28 is a cross-sectional view illustrating a configuration example of an imaging device according to a sixth embodiment.

FIG. 29 is a cross-sectional view illustrating a configuration example of an imaging device according to a seventh embodiment.

FIG. 30 is a cross-sectional view illustrating a configuration example of an imaging device according to an eighth embodiment.

FIG. 31 is a cross-sectional view illustrating a configuration of an imaging device according to a ninth embodiment.

FIG. 32 is a plan view illustrating a configuration example of a first uneven structure on a first surface side.

FIG. 33 is a plan view illustrating a configuration example of a first uneven structure on a first surface side.

FIG. 34 is a plan view illustrating a configuration example of a first uneven structure on a first surface side.

FIG. 35 is a plan view illustrating a configuration example of a first uneven structure on a first surface side.

FIG. 36 is a plan view illustrating a configuration example of a second uneven structure on a second surface F2 side.

FIG. 37 is a plan view illustrating a configuration example of a second uneven structure on a second surface F2 side.

FIG. 38 is a plan view illustrating a configuration example of a second uneven structure on a second surface F2 side.

FIG. 39 is a plan view illustrating a configuration example of a second uneven structure on a second surface F2 side.

FIG. 40 is a plan view illustrating a configuration example of a second uneven structure on a second surface F2 side.

FIG. 41 is a plan view illustrating a configuration example of a second uneven structure on a second surface F2 side.

FIG. 42 is a plan view illustrating a configuration example of a first or second uneven structure.

FIG. 43 is a plan view illustrating a configuration example of a first or second uneven structure.

FIG. 44 is a plan view illustrating a configuration example of a first or second uneven structure.

FIG. 45 is a plan view illustrating a configuration example of a first or second uneven structure.

FIG. 46 is a plan view illustrating a configuration example of a first or second uneven structure.

FIG. 47 is a cross-sectional view illustrating a configuration example of an imaging device according to a tenth embodiment.

FIG. 48 is a plan view illustrating a configuration example of a reflection member.

FIG. 49 is a plan view illustrating a configuration example of a reflection member.

FIG. 50 is a plan view illustrating a configuration example of a reflection member.

FIG. 51 is a plan view illustrating a configuration example of a reflection member.

FIG. 52 is a cross-sectional view illustrating a configuration example of an imaging device according to an eleventh embodiment.

FIG. 53 is a block diagram illustrating a schematic configuration example of a vehicle control system as an example of a moving body control system to which the technology according to the present disclosure can be applied.

FIG. 54 is a diagram illustrating an example of an installation position of an imaging section.

### MODE FOR CARRYING OUT THE INVENTION

Specific embodiments to which the present technology is applied will be described below in detail with reference to the drawings. The drawings are schematic or conceptual, and the ratio of each part and the like are not necessarily the same as actual ones. In the specification and the drawings, elements similar to the elements previously described with reference to previously described drawings are denoted by the same reference numerals, and the detailed description thereof will be omitted as appropriate.

### First Embodiment

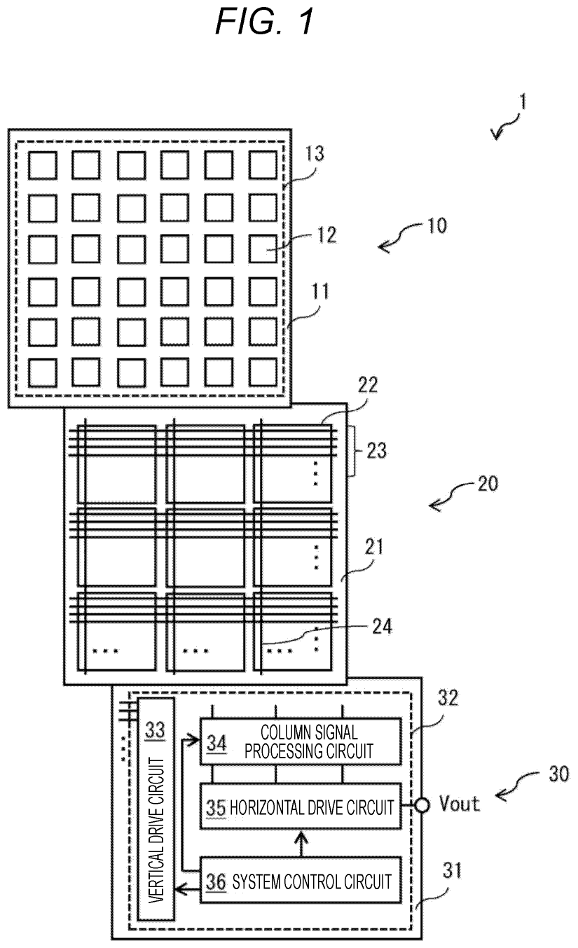

FIG. 1 is a schematic diagram illustrating a configuration example of an imaging device 1 according to a first embodiment. The imaging device 1 includes a first substrate 10, a second substrate 20, and a third substrate 30. The imaging device 1 has a three-dimensional structure formed by bonding the first to third substrates 10, 20, and 30. The first substrate 10, the second substrate 20, and the third substrate 30 are stacked in this order.

The first substrate 10 includes a plurality of pixels 12 that performs photoelectric conversion on a semiconductor substrate 11. The semiconductor substrate 11 is, for example, a silicon substrate. The plurality of pixels 12 is provided in a matrix in a pixel region 13 of the first substrate 10. The second substrate 20 includes, on a semiconductor substrate 21, one readout circuit 22 for every four pixels 12, the readout circuit 22 outputting a pixel signal based on electric charge output from the pixel 12. The semiconductor substrate 21 is, for example, a silicon substrate. The second substrate 20 includes a plurality of pixel drive lines 23 extending in the row direction and a plurality of vertical signal lines 24 extending in the column direction. The third substrate 30 includes, on a semiconductor substrate 31, a logic circuit 32 that processes pixel signals. The semiconductor substrate 31 is, for example, a silicon substrate. The logic circuit 32 includes, for example, a vertical drive circuit 33, a column signal processing circuit 34, a horizontal drive circuit 35, and a system control circuit 36. The logic circuit 32 (specifically, the horizontal drive circuit 35) outputs an output voltage Vout for each pixel 12 to the outside. In the logic circuit 32, a low-resistance region including silicide such as CoSi₂ or NiSi may be formed on a surface of an impurity diffusion region that is in contact with a source electrode and a drain electrode, for example.

The vertical drive circuit 33 sequentially selects the plurality of pixels 12 row by row, for example. The column signal processing circuit 34 performs, for example, correlated double sampling (CDS) processing on the pixel signal output from each pixel 12 in the row selected by the vertical drive circuit 33. The column signal processing circuit 34 extracts a signal level of a pixel signal by performing CDS processing, for example, and holds pixel data corresponding to the amount of light received by each pixel 12. The horizontal drive circuit 35 sequentially outputs the pixel data held in the column signal processing circuit 34 to the outside, for example. The system control circuit 36 controls driving of each block (vertical drive circuit 33, column signal processing circuit 34, and horizontal drive circuit 35) in the logic circuit 32, for example.

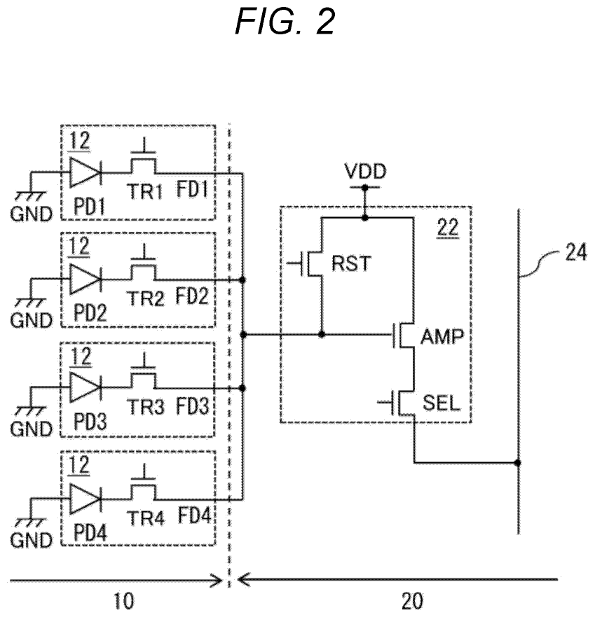

FIG. 2 is a circuit diagram illustrating an example of the pixel 12 and the readout circuit 22. Hereinafter, as illustrated in FIG. 2, a case where four pixels 12 share one readout circuit 22 will be described. Here, “sharing” means that the outputs of the four pixels 12 are input to a common readout circuit 22.

The pixels 12 have common components. In FIG. 2, in order to distinguish the components of the sensor pixels 12 from each other, identification numbers (1, 2, 3, and 4) are added to the end of the reference signs of the components of the pixels 12. In the following, in a case where it is necessary to distinguish the components of the pixels 12 from each other, the identification number is attached to the end of the reference sign of the component of each pixel 12, but in a case where it is not necessary to distinguish the components of the pixels 12 from each other, the identification number at the end of the reference sign of the component of each pixel 12 is omitted.

Each pixel 12 includes, for example, a photodiode PD, a transfer transistor TR electrically connected to the photodiode PD, and a floating diffusion FD that temporarily holds electric charge output from the photodiode PD via the transfer transistor TR. The photodiode PD corresponds to a specific example of a “photoelectric conversion element” of the present technology. The photodiode PD generates electric charge corresponding to an amount of received light by photoelectric conversion. The cathode of the photodiode PD is electrically connected to the source of the transfer transistor TR, and the anode of the photodiode PD is electrically connected to a reference potential line (for example, ground). The drain of the transfer transistor TR is electrically connected to the floating diffusion FD, and the gate of the transfer transistor TR is electrically connected to the pixel drive line 23. The transfer transistor TR is, for example, a CMOS transistor.

The floating diffusions FD of the pixels 12 sharing one readout circuit 22 are electrically connected to each other and are electrically connected to the input end of the common readout circuit 22. The readout circuit 22 includes, for example, a reset transistor RST, a selection transistor SEL, and an amplification transistor AMP. Note that the selection transistor SEL may be omitted as necessary. The source of the reset transistor RST (the input end of the readout circuit 22) is electrically connected to the floating diffusion FD, and the drain of the reset transistor RST is electrically connected to a power supply line VDD and the drain of the amplification transistor AMP. The gate of the reset transistor RST is electrically connected to the pixel drive line 23 (see FIG. 1). The source of the amplification transistor AMP is electrically connected to the drain of the selection transistor SEL, and the gate of the amplification transistor AMP is electrically connected to the source of the reset transistor RST. The source of the selection transistor SEL (the output end of the readout circuit 22) is electrically connected to the vertical signal line 24, and the gate of the selection transistor SEL is electrically connected to the pixel drive line 23 (see FIG. 1).

The transfer transistor TR transfers electric charge of the photodiode PD to the floating diffusion FD when turned on. The reset transistor RST resets the potential of the floating diffusions FD to a predetermined potential. The reset transistor RST resets the potential of the floating diffusions FD to a potential of the power supply line VDD when turned on. The selection transistor SEL controls the output timing of the pixel signal from the readout circuit 22. The amplification transistor AMP generates a voltage signal corresponding to the amount of electric charge held in the floating diffusion FD as a pixel signal. The amplification transistor AMP forms a source follower type amplifier, and outputs a pixel signal having a voltage corresponding to the amount of electric charge generated in the photodiode PD. When the selection transistor SEL is turned on, the amplification transistor AMP amplifies the potential of the floating diffusion FD, and outputs a voltage corresponding to the potential to the column signal processing circuit 34 via the vertical signal line 24. The reset transistor RST, the amplification transistor AMP, and the selection transistor SEL are, for example, CMOS transistors.

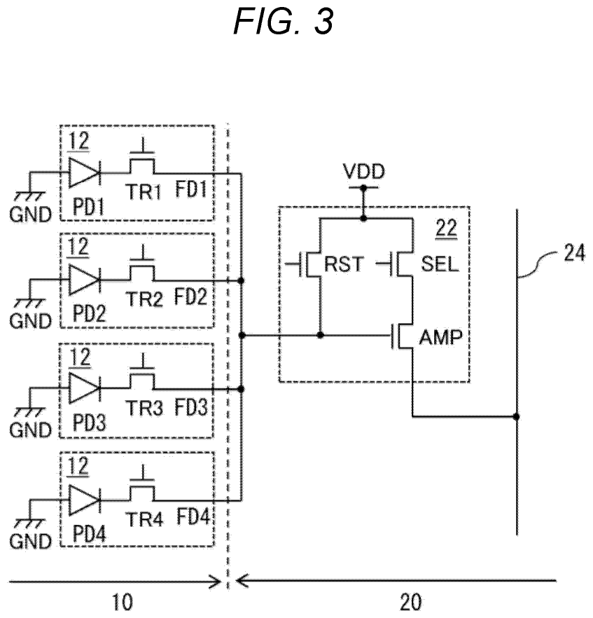

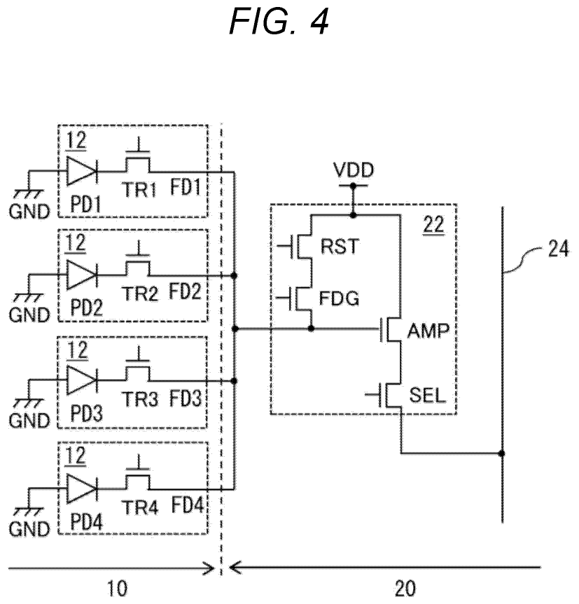

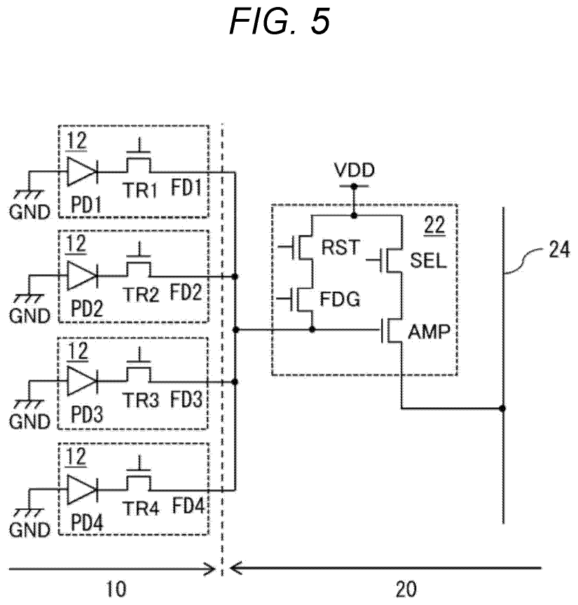

Note that as illustrated in FIG. 3, the selection transistor SEL may be provided between the power supply line VDD and the amplification transistor AMP. Furthermore, as illustrated in FIGS. 4 and 5, an FD transfer transistor FDG may be provided between the source of the reset transistor RST and the gate of the amplification transistor AMP.

The FD transfer transistor FDG is used to switch the conversion efficiency. In general, a pixel signal is small at the time of imaging in a dark place. On the basis of Q=CV, if the capacitance (FD capacitance C) of the floating diffusion FD is large at the time of performing charge-voltage conversion, an FD voltage V at the time of conversion into a voltage by the amplification transistor AMP becomes small. On the other hand, since the pixel signal becomes large in a bright place, if the FD capacitance C is small, the floating diffusion FD cannot fully receive the electric charge of the photodiode PD. Furthermore, the FD capacitance C needs to be large so that V at the time of conversion into a voltage by the amplification transistor AMP does not become too large (in other words, is made smaller.). In view of these circumstances, when the FD transfer transistor FDG is turned on, the gate capacitance corresponding to the FD transfer transistor FDG increases, and thus the entire FD capacitance C increases. On the other hand, when the FD transfer transistor FDG is turned off, the entire FD capacitance C decreases. In this manner, by switching the FD transfer transistor FDG on and off, the FD capacitance C can be made variable, and the conversion efficiency can be switched.

FIG. 6 is a diagram illustrating an example of a connection mode between a plurality of readout circuits 22 and a plurality of vertical signal lines 24. In a case where the plurality of readout circuits 22 is arranged side by side in the extending direction (for example, the column direction) of the vertical signal line 24, the plurality of vertical signal lines 24 may be allocated one by one to each readout circuit 22. For example, as illustrated in FIG. 6, in a case where four readout circuits 22 are arranged side by side in the extending direction (for example, the column direction) of the vertical signal line 24, one of the four vertical signal lines 24 may be allocated to each readout circuit 22.

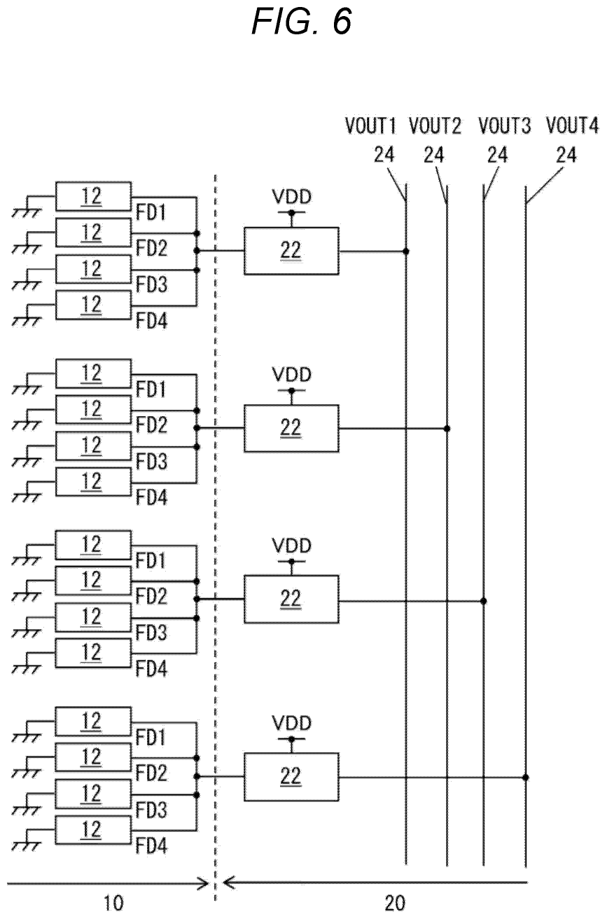

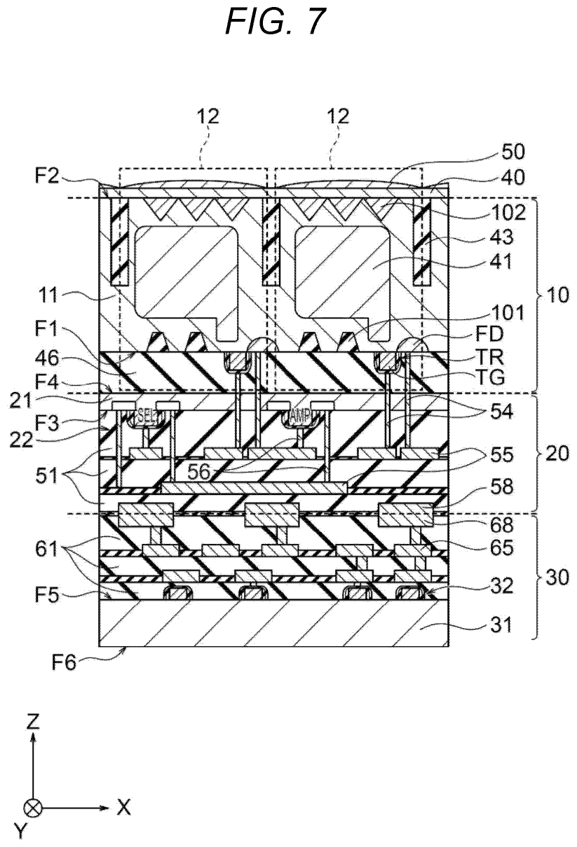

FIG. 7 is a diagram illustrating an example of a vertical cross-sectional configuration of the imaging device 1. FIG. 7 illustrates a cross-sectional configuration of a part of the imaging device 1 facing the pixel 12. The imaging device 1 is formed by stacking the first substrate 10, the second substrate 20, and the third substrate 30 in this order. Note that in FIG. 7, the first and second substrates 10 and 20 are disposed with a first surface F1 side and a third surface F3 (front surface) side facing the −Z direction (downward). On the other hand, the third substrate 30 is disposed with a fifth surface F5 (front surface) side facing the +Z direction (upward). Therefore, the description of upper and lower directions may be inverted between the third substrate 30 and the first and second substrates 10 and 20.

The first substrate 10 includes the semiconductor substrate 11 as a first semiconductor substrate. As the semiconductor substrate 11, for example, a p-type silicon substrate is used, or a p-type well is provided. A color filter 40 and a light receiving lens 50 are provided on a second surface F2 of the semiconductor substrate 11. The second surface (back surface) F2 of the semiconductor substrate 11 is a light incident surface on which light is incident. For example, one color filter 40 and one light receiving lens 50 are provided for each pixel 12. As described above, the imaging device 1 is a back-illuminated CIS.

On the other hand, an insulating layer 46 is provided on the first surface (front surface) F1 of the semiconductor substrate 11. The insulating layer 46 is provided between the semiconductor substrate 11 and a semiconductor substrate 21. For the insulating layer 46, for example, an insulating material such as a silicon oxide film is used.

In the semiconductor substrate 11, an n-type photo diode (PD) 41 is provided for each pixel 12. The PD 41 includes an n-type semiconductor region. Further, the floating diffusion FD is provided on the first surface F1 side of the semiconductor substrate 11. The floating diffusion FD includes, for example, an n-type semiconductor region. In addition, the transfer transistor TR is provided on the first surface F1 side of the semiconductor substrate 11. The transfer transistor TR is disposed in the vicinity of the PD 41 and the floating diffusion FD, and transfers the electric charge accumulated in the PD 41 to the floating diffusion FD.

The first substrate 10 includes a photodiode PD, a transfer transistor TR, and a floating diffusion FD for each pixel 12. The first substrate 10 includes the transfer transistor TR and the floating diffusion FD on the first surface F1 side opposite to the second surface (light incident surface) F2. The first substrate 10 includes element isolation parts 43 that electrically isolate the pixels 12 adjacent to each other. The element isolation part 43 is provided between two pixels 12 adjacent to each other. The element isolation part 43 extends in a direction perpendicular to the first surface F1 or the second surface F2 of the semiconductor substrate 11 (light incident direction: Z direction). The element isolation part 43 is, for example, a deep trench isolation (DTI) formed with a predetermined depth from the second surface F2 of the semiconductor substrate 11. Note, however, that the element isolation part 43 may penetrate the semiconductor substrate 11 from the second surface F2 to the first surface F1 of the semiconductor substrate 11. For the element isolation part 43, for example, an insulating material such as a silicon oxide film is used.

Although not illustrated, the first substrate 10 may have, for example, a p-type pinning layer provided on a side surface of the element isolation part 43 and a negative fixed charge film in contact with the second surface F2 of the semiconductor substrate 11. The fixed charge film is negatively charged in order to curb generation of a dark current due to an interface state on the light-receiving side of the semiconductor substrate 11.

The second substrate 20 includes the semiconductor substrate 21. As the semiconductor substrate 21, for example, a p-type silicon substrate is used, or a p-type well is provided. The fourth surface (back surface) F4 of the semiconductor substrate 21 is bonded to the insulating layer 46 on the first surface (front surface) F1 side of the first substrate 10. That is, the second substrate 20 is bonded to the first substrate 10 in a face-to-back manner.

On the other hand, an interlayer insulating film 51 and a wiring layer 55 are provided on the third surface (front surface) F3 side of the semiconductor substrate 21. The interlayer insulating film 51 and the wiring layer 55 are stacked between the semiconductor substrate 21 and the semiconductor substrate 31, and are formed as a multilayer wiring layer. For the interlayer insulating film 51, for example, an insulating material such as a silicon oxide film is used. For the wiring layer 55, for example, a low-resistance metal material such as copper is used.

The second substrate 20 includes, for example, one readout circuit 22 for every four pixels 12. The second substrate 20 includes the readout circuit 22 on the third surface F3 of the semiconductor substrate 21. The readout circuit 22 includes, for example, the amplification transistor AMP, the selection transistor SEL, and the reset transistor RST. Thus, the readout circuit 22 can output the pixel signal based on the electric charge output from the plurality of pixels 12 to the logic circuit 32 of the third substrate 30.

An electrode plug 54 is provided between the first substrate 10 and the second substrate 20. The electrode plug 54 is connected, for example, between a part of the wiring layer 55 of the second substrate 20 and the floating diffusion FD of the first substrate 10, or between a part of the wiring layer 55 of the second substrate 20 and a gate electrode TG of the transfer transistor TR of the first substrate 10. The electrode plug 54 can penetrate the interlayer insulating film 51 and the insulating layer 46 in the Z direction to electrically connect the first substrate 10 and the second substrate 20.

An electrode plug 56 is provided in the interlayer insulating film 51 of the second substrate 20. The electrode plug 56 extends in the Z direction in the interlayer insulating film 51, and connects, for example, the gate, the source, or the drain of the amplification transistor AMP, the selection transistor SEL, the reset transistor RST, or the like forming the readout circuit 22, and any of the wiring layers 55. For the electrode plugs 54 and 56, for example, a low-resistance metal material such as copper or tungsten is used.

The wiring layer 55 includes, for example, a plurality of pixel drive lines and a plurality of vertical signal lines. Therefore, the transfer transistor TR is connected to the gate electrode TG of the transfer transistor TR from the wiring layer 55 via the electrode plug 54.

Furthermore, in a case where one readout circuit 22 is provided for every four pixels 12, the wiring layer 55 includes wiring connecting the four floating diffusions FD and one amplification transistor AMP.

A plurality of pad electrodes 58 is provided on the third substrate 30 side as a part of the wiring layer 55, and is exposed from the interlayer insulating film 51 of the second substrate 20. For each pad electrode 58, a low-resistance metal material such as copper (Cu) or aluminum (Al) is used. Each pad electrode 58 is used for electrical connection between the second substrate 20 and the third substrate 30 and bonding between the second substrate 20 and the third substrate 30.

The third substrate 30 includes the semiconductor substrate 31. As the semiconductor substrate 31, for example, a p-type silicon substrate is used, or a p-type well is provided. The fifth surface (front surface) F5 of the semiconductor substrate 31 is provided with an interlayer insulating film 61 and a wiring layer 65. The interlayer insulating film 61 and the wiring layer 65 are stacked between the semiconductor substrate 31 and the second substrate 20, and are formed as a multilayer wiring layer. For the interlayer insulating film 61, for example, an insulating material such as a silicon oxide film is used. For the wiring layer 65, for example, a low-resistance metal material such as copper is used.

Furthermore, the interlayer insulating film 61 on the fifth surface (front surface) side of the third substrate 30 is bonded to the interlayer insulating film 51 on the third surface (front surface) F3 side of the second substrate 20. That is, the third substrate 30 is bonded to the second substrate 20 in a face-to-face manner.

The third substrate 30 includes the logic circuit 32 provided on the fifth surface F5 of the semiconductor substrate 31. A plurality of pad electrodes 68 is provided on the second substrate 20 side as a part of the wiring layer 65, and is exposed from the interlayer insulating film 61 of the third substrate. For each pad electrode 68, a low-resistance metal material such as copper (Cu) or aluminum (Al) is used. Each pad electrode 68 is used for electrical connection between the second substrate 20 and the third substrate 30 and bonding between the second substrate 20 and the third substrate 30. The second substrate 20 and the third substrate 30 are electrically connected to each other by bonding the pad electrodes 58 and the pad electrodes 68. The pad electrodes 68 are electrically connected to the logic circuit 32 via another wiring layer 65. Therefore, the readout circuit 22 is electrically connected to any one of the logic circuits 32 via the electrode plug 54, the wiring layer 55, the pad electrodes 58 and 68, and the wiring layer 65. For example, gate electrodes of the transfer transistor TR, the selection transistor SEL, and the reset transistor RST are electrically connected to any one of the logic circuits 32 via the electrode plug 54, the wiring layer 55, the pad electrodes 58 and 68, and the wiring layer 65.

Here, a first uneven structure 101 is provided on the first surface F1 of the semiconductor substrate 11 of the first substrate 10 so as to protrude in the Z direction toward the PD 41. The first uneven structure 101 includes a material different from that of the semiconductor substrate 11. For example, in a case where silicon single crystal is used for the semiconductor substrate 11, a material having a refractive index lower than that of the semiconductor substrate 11, such as a silicon oxide film, is desired for the first uneven structure 101. As a result, light incident on the pixel 12 from the second surface F2 is easily diffracted or reflected at the interface between the semiconductor substrate 11 and the first uneven structure 101.

In addition, a second uneven structure 102 is provided on the second surface F2 of the semiconductor substrate 11 so as to protrude in the −Z direction toward the PD 41. The second uneven structure 102 also includes a material different from that of the semiconductor substrate 11. For example, in a case where silicon single crystal is used for the semiconductor substrate 11, a material having a refractive index lower than that of the semiconductor substrate 11, such as a silicon oxide film, is desired for the second uneven structure 102. As a result, light easily enters the pixel 12 from the second surface

F2, and is easily diffracted or reflected at the interface between the semiconductor substrate 11 and the second uneven structure 102.

As described above, light is diffracted or reflected at the interface between the semiconductor substrate 11 and the first uneven structure 101 and the interface between the semiconductor substrate 11 and the second uneven structure 102, so that photoelectric conversion efficiency in the PD 41 is improved. In addition, as more light is diffracted or reflected at the interface between the semiconductor substrate 11 and the first uneven structure 101, less light enters the second and third substrates 20 and 30. This leads to curbing of dark current and noise in the readout circuit 22 of the second substrate 20 or curbing of malfunction in the logic circuit 32 of the third substrate 30.

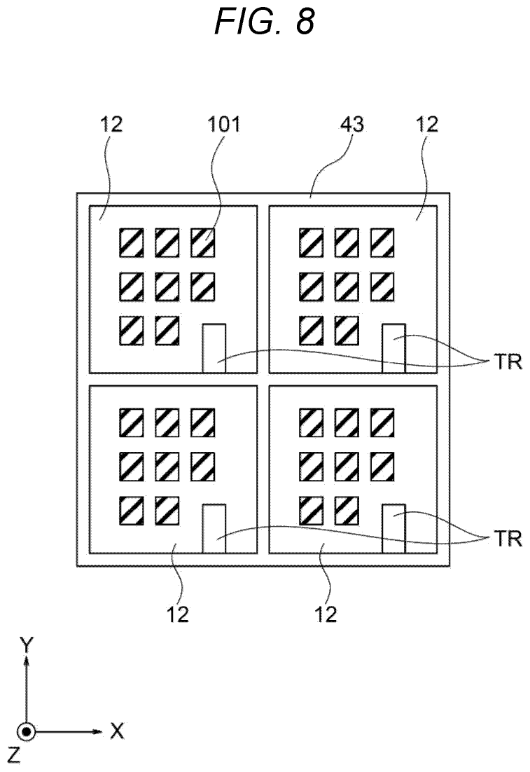

FIG. 8 is a plan view illustrating an example of a planar layout of the first uneven structure 101 and the transfer transistor TR. FIG. 8 illustrates the arrangement of the first uneven structure 101 and the transfer transistor TR in plan view as viewed from the light incident direction (Z direction).

FIG. 8 illustrates the first uneven structure 101 corresponding to four pixels 12. In one pixel 12, a plurality of first uneven structures 101 is arranged, and the transfer transistor TR is arranged at an end. As illustrated in FIG. 7, the first uneven structure 101 has a substantially trapezoidal shape in a cross section perpendicular to the first surface F1 (a cross section in the Z direction), and as illustrated in FIG. 8, has a substantially quadrangular shape in plan view from the Z direction. Therefore, the first uneven structure 101 is formed in a substantially quadrangular frustum shape. In the first embodiment, the first uneven structures 101 are arranged in the X direction and the Y direction orthogonal to the X direction, and are two-dimensionally arranged in a matrix. For example, in one pixel 12, the first uneven structures 101 are arranged in three rows and three columns in a region other than the transfer transistor TR. The arrangement and number of the first uneven structures 101 are not particularly limited, and the first uneven structures 101 may be arranged in two rows or less or four rows or more, and two columns or less or four columns or more.

The element isolation part 43 is provided in a lattice shape between the pixels 12 adjacent to each other. The element isolation part 43 optically and electrically isolates the adjacent pixels 12 from each other to partition the pixels 12. As illustrated in FIG. 7, the element isolation part 43 is a DTI formed from the second surface F2.

As illustrated in FIG. 8, in plan view as viewed from the Z direction, the transfer transistor TR is arranged at substantially the same position when the pixel 12 is translated. That is, the transfer transistors TR are arranged at substantially the same position in the pixels 12. As a result, the optical symmetry of the pixel 12 is improved, and variations in characteristics and sensitivity among the pixels 12 can be curbed.

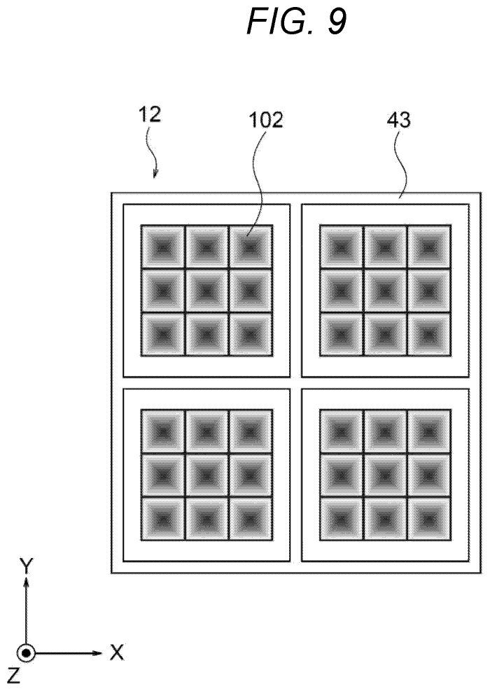

FIG. 9 is a plan view illustrating an example of a planar layout of the second uneven structure 102. FIG. 9 illustrates the arrangement of the second uneven structure 102 in plan view as viewed from the light incident direction (Z direction).

FIG. 9 illustrates the second uneven structure 102 corresponding to four pixels 12. A plurality of second uneven structures 102 is arranged in one pixel 12. As illustrated in FIG. 7, the second uneven structure 102 has a substantially triangular shape in a cross section perpendicular to the second surface F2 (a cross section in the Z direction), and as illustrated in FIG. 9, has a substantially quadrangular shape in plan view from the Z direction. Therefore, the second uneven structure 102 is formed in a substantially quadrangular pyramid shape. In the first embodiment, the second uneven structures 102 are arranged in the X direction and the Y direction orthogonal to the X direction, and are two-dimensionally arranged in a matrix. For example, in one pixel 12, the second uneven structures 102 are arranged in three rows and three columns. The arrangement and number of the second uneven structures 102 are not particularly limited, and the second uneven structures 102 may be arranged in two rows or less or four rows or more, and two columns or less or four columns or more.

With such a configuration, light is diffracted or reflected at the interface between the semiconductor substrate 11 and the first uneven structure 101 and the interface between the semiconductor substrate 11 and the second uneven structure 102, whereby photoelectric conversion efficiency in the PD 41 can be improved. The imaging device 1 according to the present embodiment can detect even near infrared light (near infrared (NIR)) with high sensitivity by increasing the photoelectric conversion efficiency of the PD 41 by the first and second uneven structures 101 and 102. In addition, since less light enters the second and third substrates 20 and 30 from the interface between the semiconductor substrate 11 and the first uneven structure 101, dark current and noise in the readout circuit 22 of the second substrate 20 can be curbed, or malfunction in the logic circuit 32 of the third substrate 30 can be curbed.

According to the present embodiment, the pixel transistor (amplification transistor AMP, selection transistor SEL, reset transistor RST, and the like) of the readout circuit 22 is provided on the second substrate 20 different from the first substrate 10 including the pixel 12. As described above, by forming the substrates 10 and 20 in a stacked structure, a space for providing the first uneven structure 101 on the first surface F1 of the semiconductor substrate 11 can be provided. Accordingly, the first uneven structure 101 can be formed in a wide space on the first surface F1. As a result, light is sufficiently diffracted or reflected to the PD 41, the photoelectric conversion efficiency in the PD 41 can be improved, and light entering the second and third substrates 20 and 30 can be curbed.

In addition, since the first and second uneven structures 101 and 102 are substantially uniformly arranged in each pixel 12, optical symmetry in each pixel 12 can be improved.

Next, a method for manufacturing the imaging device 1 according to the first embodiment will be described.

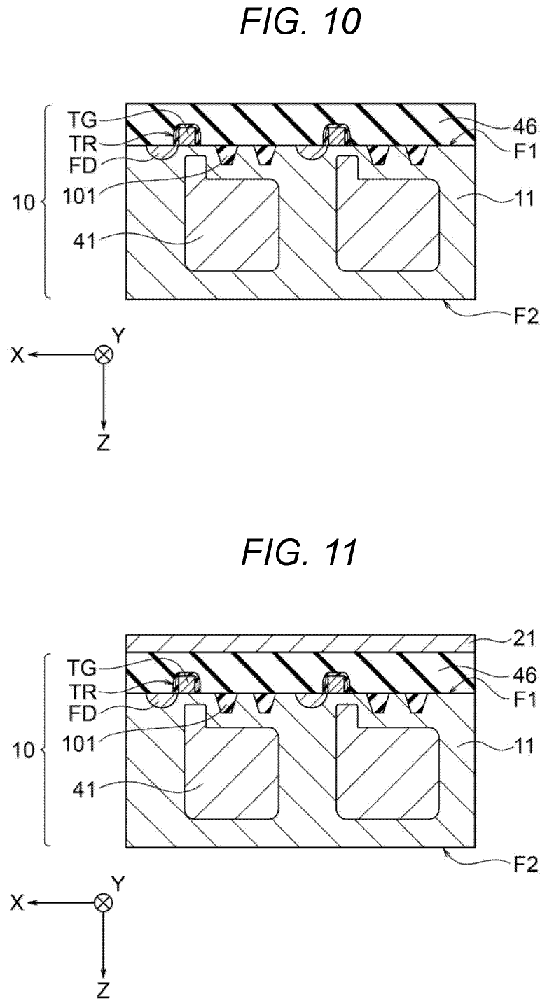

FIGS. 10 to 15 are cross-sectional views illustrating an example of the manufacturing method of the imaging device 1 according to the first embodiment. Note that in FIG. 10, the first substrate 10 is vertically inverted from the first substrate 10 illustrated in FIG. 7.

First, the semiconductor substrate 11 having the first surface F1 and the second surface F2 opposite to the first surface F1 is prepared. For the semiconductor substrate 11, for example, a semiconductor such as p-type silicon is used. Next, using a lithography technique and an implant technique, for example, n-type impurities are introduced into the semiconductor substrate 11, and the PD 41 is formed in the semiconductor substrate 11.

Next, a trench is formed in a formation region of the first uneven structure 101 on the first surface F1 using a lithography technique and an etching technique. Next, an insulating material such as a silicon oxide film is embedded in this trench using a chemical vapor deposition (CVD) method or the like. Thus, the first uneven structure 101 is formed.

Next, a material (for example, polysilicon) of the gate electrode TG of the transfer transistor TR is deposited, and the material of the gate electrode TG is processed using a lithography technique and an etching technique. Thus, the gate electrode TG is formed. Spacers (for example, a silicon oxide film) are formed on a side surface and an upper surface of the gate electrode TG as necessary.

Next, an n-type impurity is introduced into the first surface F1 of the semiconductor substrate 11 using a lithography technique and an implant technique to form the floating diffusion FD.

Next, the insulating layer 46 such as a silicon oxide film is deposited on the first surface F1. Thus, the structure illustrated in FIG. 10 is obtained.

Next, the semiconductor substrate 21 having the third surface F3 and the fourth surface F4 opposite to the third surface F3 is prepared. For the semiconductor substrate 21, for example, a semiconductor such as p-type silicon is used.

Next, the fourth surface F4 of the semiconductor substrate 21 is bonded onto the insulating layer 46. Next, as illustrated in FIG. 11, the semiconductor substrate 21 is thinned by using a chemical mechanical polishing (CMP) method.

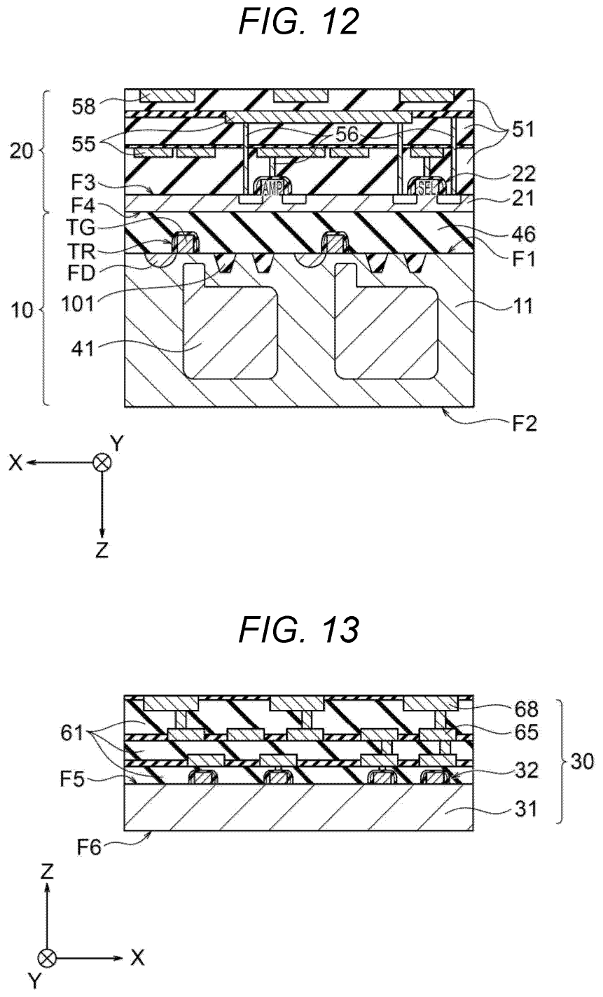

Next, as illustrated in FIG. 12, the readout circuit 22 including the amplification transistor AMP, the selection transistor SEL, and the like is formed on the third surface F3 of the semiconductor substrate 21. A known semiconductor wafer process only needs to be used as a method of manufacturing the readout circuit 22.

Next, the interlayer insulating film 51 is deposited on the third surface F3, and the readout circuit 22 is covered with the interlayer insulating film 51. Next, a contact hole is formed in a formation region of the electrode plug 56 so as to penetrate the interlayer insulating film 51 using a lithography technique and an etching technique. As a result, the contact hole is formed so as to reach the gate electrode, the source, or the drain of the amplification transistor AMP, the selection transistor SEL, or the like. Next, a metal (for example, copper, tungsten, and the like) is embedded in the contact hole. As a result, the electrode plug 56 is formed as illustrated in FIG. 12.

Next, the wiring layer 55 is formed on the interlayer insulating film 51 or the electrode plug 56.

By repeating the formation of the interlayer insulating film 51, the electrode plug 56, and the wiring layer 55 in this manner, a multilayer wiring layer including the interlayer insulating film 51 and the wiring layer 55 as illustrated in FIG. 12 is formed. In addition, the electrode plug 56 that connects the wiring layer 55 and the readout circuit 22 is formed in the interlayer insulating film 51.

Next, the semiconductor substrate 31 having the fifth surface F5 and the sixth surface F6 opposite to the fifth surface F5 is prepared. For the semiconductor substrate 31, for example, a semiconductor such as p-type silicon is used. Next, as illustrated in FIG. 13, the logic circuit 32 including a complementary metal oxide semiconductor (CMOS) circuit and the like is formed on the fifth surface F5 of the semiconductor substrate 31. A known semiconductor wafer process only needs to be used as a method of manufacturing the logic circuit 32.

Next, the interlayer insulating film 61 and the wiring layer 65 are formed on the fifth surface F5. In addition, a contact plug is formed on the interlayer insulating film 61 as necessary. As a result, a multilayer wiring layer including the interlayer insulating film 51 and the wiring layer 55 as illustrated in FIG. 13 is formed.

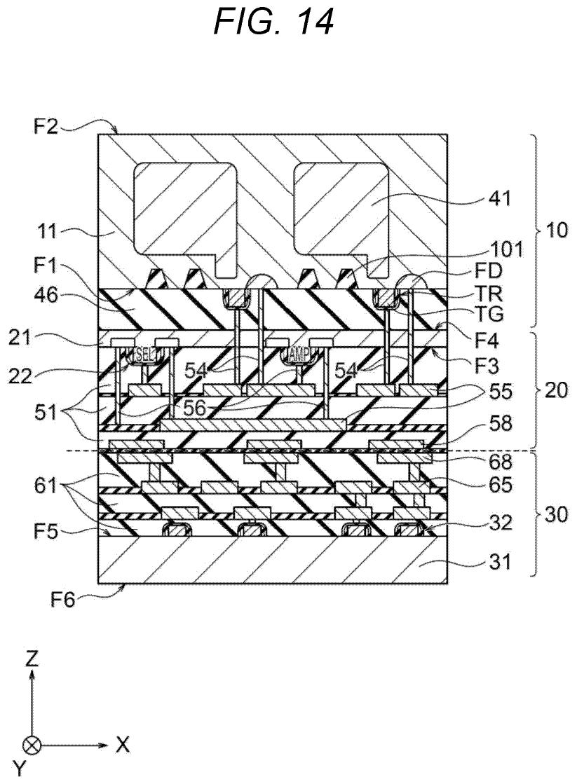

Next, as illustrated in FIG. 14, the surface of the interlayer insulating film 51 of the second substrate 20 and the surface of the interlayer insulating film 61 of the third substrate 30 are bonded to each other. As a result, the exposed surface of the pad electrode 58 of the second substrate 20 and the exposed surface of the wiring layer 65 of the third substrate 30 are bonded, and the pad electrode 58 and the wiring layer 65 are electrically connected.

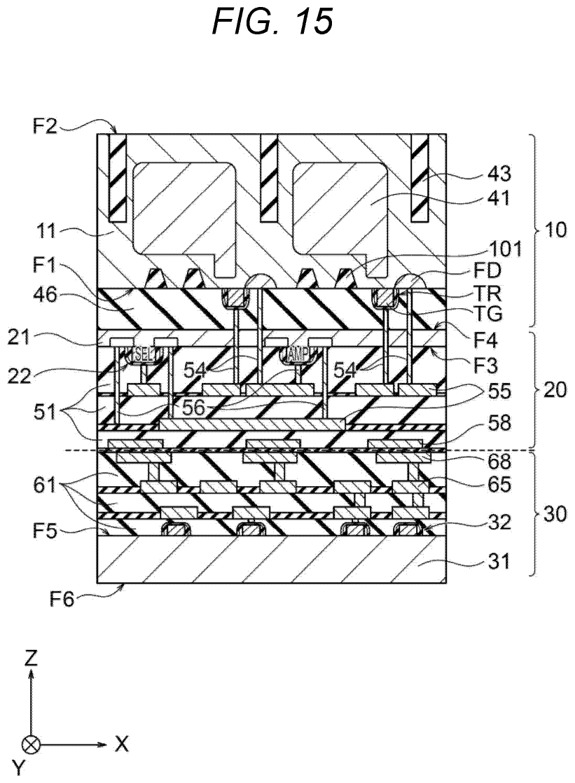

Next, a trench is formed in a formation region of the element isolation part 43 using a lithography technique and an etching technique. Next, the trench is filled with an insulating material (for example, a silicon oxide film). As a result, as illustrated in FIG. 15, the element isolation part 43 is formed.

Next, each formation region of the second uneven structure 102 is processed on the second surface F2 of the semiconductor substrate 11 using a lithography technique and an etching technique. At this time, the semiconductor substrate 11 is isotropically wet etched from the second surface F2 to form a substantially quadrangular pyramidal recess in each formation region of the second uneven structure 102. Next, the second uneven structure 102 illustrated in FIGS. 7 to 9 is formed by filling the recess with an insulating material such as a silicon oxide film.

Next, the color filter 40 and the light receiving lens 50 are formed on the second surface F2 of the semiconductor substrate 11. Thus, the imaging device 1 according to the present embodiment is completed.

As described above, according to the present embodiment, the pixel 12 and the transfer transistor are formed on the first substrate 10, the pixel transistor (amplification transistor AMP, selection transistor SEL, reset transistor RST, and the like) of the readout circuit 22 is formed on another second substrate 20, and then the first substrate 10 and the second substrate 20 are bonded together. As a result, it is not necessary to form a pixel transistor on the first substrate 10, and a space for providing the first uneven structure 101 on the first surface F1 of the semiconductor substrate 11 can be provided. As a result, the first uneven structure 101 can be formed in a region of the first surface F1 corresponding to the PD 41. As a result, light can be sufficiently reflected to the PD 41, photoelectric conversion efficiency in the PD 41 can be improved, and light entering the second and third substrates 20 and 30 can be curbed.

In the present embodiment, the second uneven structure 102 is further provided on the second surface F2. Therefore, the photoelectric conversion efficiency of the PD 41 can be further improved by diffracting or reflecting light between the first uneven structure 101 and the second uneven structure 102. Therefore, the imaging device 1 according to the present embodiment can detect even near infrared light with high sensitivity.

### Second Embodiment

FIG. 16 is a cross-sectional view illustrating a configuration example of an imaging device 1 according to a second embodiment. According to the second embodiment, an element isolation part 43 is provided so as to penetrate a first surface F1 and a second surface F2 in the Z direction. That is, the element isolation part 43 may be a full trench isolation (FTI). The planar layout of the element isolation part 43 may be the same as that of the first embodiment. Other configurations of the second embodiment may be similar to those of the first embodiment.

According to the second embodiment, since the element isolation part 43 is provided over the entire area between the first surface F1 and the second surface F2, light hardly leaks to an adjacent pixel 12. Therefore, crosstalk between the pixels 12 adjacent to each other is curbed, and the photoelectric conversion efficiency in the pixel 12 is improved.

In a method of manufacturing the imaging device 1 according to the second embodiment, the element isolation part 43 only needs to be formed before or after the formation of a first uneven structure 101 in FIG. 10. For example, before the formation of the first uneven structure 101 in FIG. 10, a trench penetrating a semiconductor substrate 11 is formed in a formation region of the element isolation part 43 using a lithography technique and an etching technique, and the trench is filled with an insulating material (for example, a silicon oxide film).

Alternatively, in the step of forming the element isolation part 43 illustrated in FIG. 15, the trench of the element isolation part 43 only needs to be formed deep enough to reach the first surface F1. In this way, too, the element isolation part 43 according to the second embodiment can be formed. Other manufacturing methods of the second embodiment may be similar to the manufacturing method of the first embodiment. As a result, the imaging device 1 according to the second embodiment is completed.

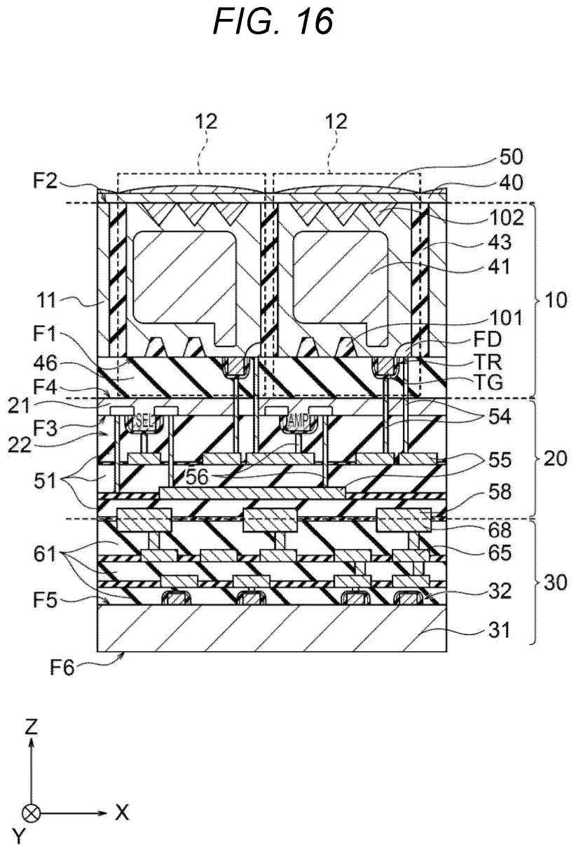

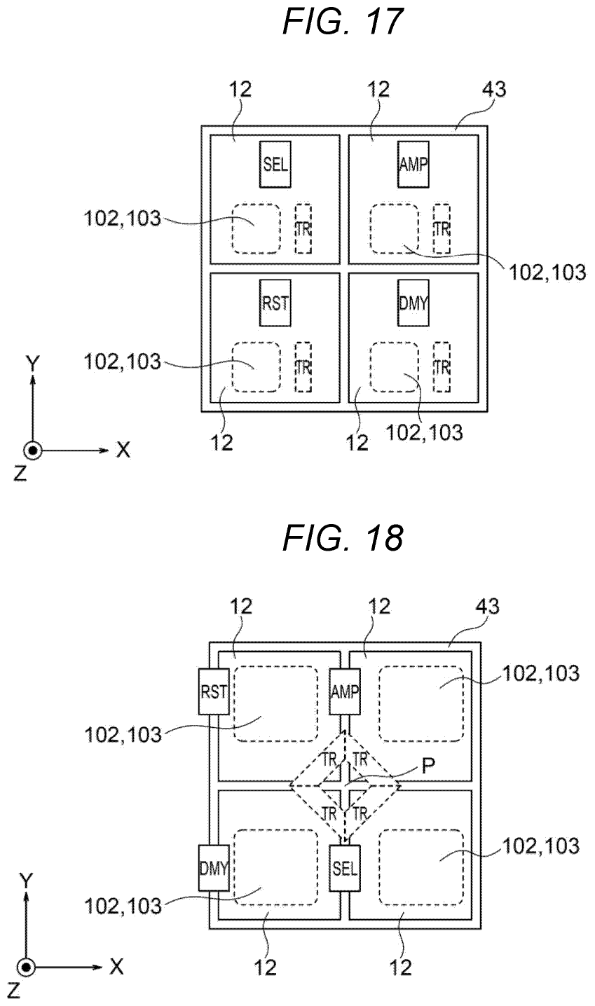

FIGS. 17 and 18 are plan views illustrating a configuration example of the imaging device 1 according to the embodiment in the present specification. FIGS. 17 and 18 illustrate the arrangement of the first and second uneven structures 101 and 102, a transfer transistor TR, and a readout circuit 22 in four pixels 12 in plan view as viewed from the Z direction. The first and second uneven structures 101 and 102, the transfer transistor TR, and the element isolation part 43 are formed on a first substrate 10. An amplification transistor AMP, a selection transistor SEL, a reset transistor RST, and a dummy transistor DMY (Hereinafter, also referred to as a pixel transistor) forming a readout circuit 22 are formed on a second substrate 20. Note that as described above, it is assumed that one readout circuit 22 is shared by four pixels 12.

In the example illustrated in FIG. 17, four pixel transistors of the amplification transistor AMP, the selection transistor SEL, the reset transistor RST, and the dummy transistor DMY forming the readout circuit 22 are arranged in different pixels 12 in the corresponding four pixels 12. The dummy transistor DMY is provided to make the optical symmetries of the four pixels 12 substantially equal to each other, and does not actually function as a pixel transistor of the readout circuit 22. The amplification transistor AMP, the selection transistor SEL, the reset transistor RST, and the dummy transistor DMY are substantially uniformly arranged at substantially the same position in each pixel 12. Furthermore, the first and second uneven structures 101 and 102 and the transfer transistor TR are also arranged at substantially the same position in each pixel 12. As a result, the optical symmetries of the four pixels 12 are substantially equal to each other.

In the example illustrated in FIG. 18, four pixel transistors of the amplification transistor AMP, the selection transistor SEL, the reset transistor RST, and the dummy transistor DMY forming the readout circuit 22 are arranged below the element isolation part 43. That is, as illustrated in FIG. 18, in plan view as viewed from the Z direction, the four pixel transistors overlap the element isolation part 43. Furthermore, the four pixel transistors are dispersed so as to be arranged substantially evenly in the four pixels 12 corresponding thereto. Furthermore, the first and second uneven structures 101 and 102 are arranged at substantially the same position in each pixel 12. The transfer transistors TR are provided so as to be close to a vertex P shared by the four pixels 12, and are arranged so as to be symmetric with respect to the vertex P. As a result, the optical symmetries of the four pixels 12 are substantially equal to each other.

Furthermore, in the example of FIG. 18, four pixel transistors of the readout circuit 22 overlap the element isolation part 43 in plan view as viewed from the light incident direction (Z direction). Therefore, the areas of the first and second uneven structures 101 and 102 can be increased in each pixel 12. At the same time, even if light leaks from the first substrate 10 to the second substrate 20 to some extent, the readout circuit 22 is hardly affected by the light.

### Third Embodiment

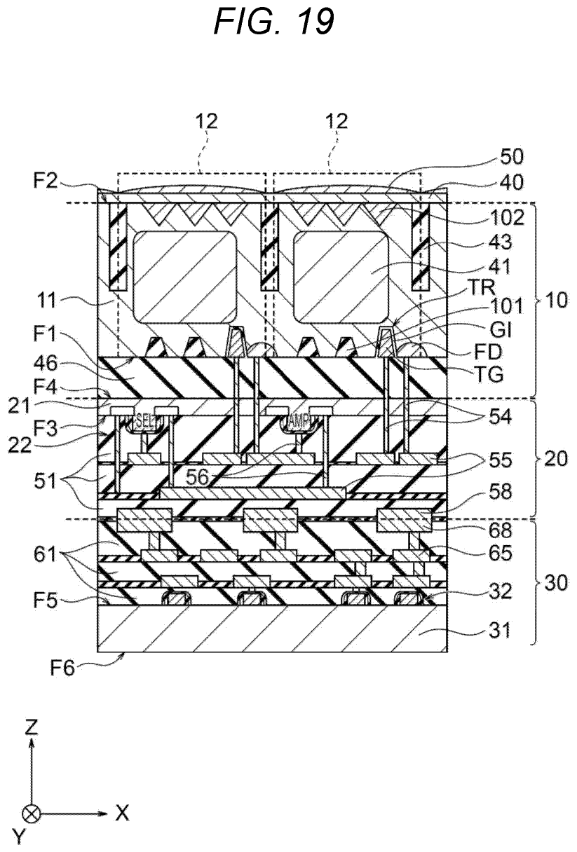

FIG. 19 is a cross-sectional view illustrating a configuration example of an imaging device 1 according to a third embodiment. According to the third embodiment, a transfer transistor TR has an embedded gate electrode TG embedded into a semiconductor substrate 11 from a first surface F1. The embedded gate electrode TG is electrically insulated from the semiconductor substrate 11 via a gate insulating film GI. The embedded gate electrode TG has a channel region in the semiconductor substrate 11 facing a side surface thereof. In a case where a side surface of the embedded gate electrode TG is inclined, an inclined channel is formed along the inclined side surface. In a case where the side surface of the embedded gate electrode TG extends in the Z direction, a vertical channel is formed in the Z direction along the side surface. Therefore, the gate electrode TG is also referred to as a vertical gate electrode. As a result, the transfer transistor TR can form a channel between a PD 41 and a floating diffusion FD, and can efficiently transfer electric charge.

Furthermore, the embedded gate electrode TG may also function as a part of a first uneven structure 101. As a result, the photoelectric conversion efficiency can be further improved, and entry of light into second and third substrates 20 and 30 can be curbed even more. Optical symmetry of the first uneven structure 101 is also improved.

Other configurations of the third embodiment may be similar to those of the first embodiment. Therefore, the third embodiment can also obtain effects similar to those of the first embodiment.

A method of forming the embedded gate electrode TG is as follows. When the transfer transistor TR is formed, a trench is formed from the first surface F1 of the semiconductor substrate 11. Next, a gate insulating film GI is formed on an inner wall of the trench, and a conductive material such as polysilicon is further embedded in the trench. As a result, the embedded gate electrode TG is formed. Other manufacturing methods of the third embodiment may be similar to the manufacturing method of the first embodiment.

Note that the third embodiment may be applied to the second embodiment. In this case, the third embodiment can obtain effects similar to those of the second embodiment.

### Fourth Embodiment

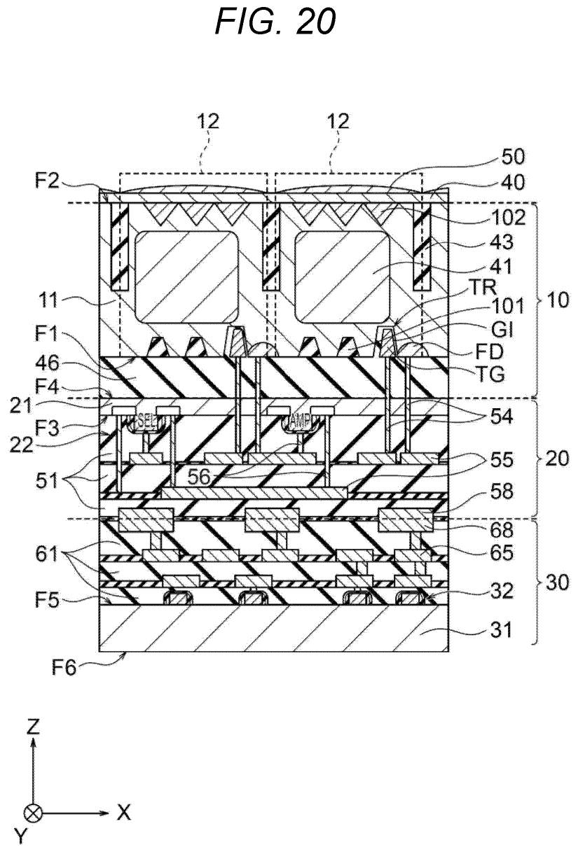

FIG. 20 is a cross-sectional view illustrating a configuration example of an imaging device 1 according to a fourth embodiment. The fourth embodiment is the same as the third embodiment in that a transfer transistor TR includes an embedded gate electrode TG. However, the thickness of a gate insulating film GI is different between a floating diffusion FD side (hereinafter also referred to as a first side surface) and the other side (hereinafter also referred to as a second side surface). For example, the thickness of a gate insulating film (first insulating film) provided on the first side surface among the side surfaces of the embedded gate electrode TG is relatively thin. On the other hand, the thickness of a gate insulating film (second insulating film) provided on the second side surface opposite to the first side surface among the side surfaces of the embedded gate electrode TG is larger than that of the first insulating film. As a result, the channel is easily formed on the first side surface of the embedded gate electrode TG, and is hardly formed on the second side surface thereof. The second side surface of the embedded gate electrode TG other than the first side surface does not contribute to charge transfer. Therefore, by making the second insulating film thicker than the first insulating film, the capacitance of the part of the embedded gate electrode TG that hardly contributes to charge transfer can be reduced. As a result, the electric field of the embedded gate electrode TG is intensively applied to the channel region on the first side surface side, and a channel can be easily and quickly formed in the semiconductor substrate 11 on the first side surface side. This leads to a reduction in the operating voltage of the transfer transistor TR and an increase in the operating speed thereof. Other configurations of the fourth embodiment may be similar to those of the third embodiment. Therefore, the fourth embodiment can also obtain the effect of the third embodiment.

The gate insulating film GI of the fourth embodiment is formed as follows. After the gate insulating film GI is formed, the gate insulating film GI of the first side surface is selectively etched using a lithography technique and an etching technique. As a result, the first insulating film can be formed thinner than the second insulating film. Thereafter, the gate insulating film TG is embedded. Other manufacturing methods of the fourth embodiment may be similar to the corresponding manufacturing method of the third embodiment.

(Modification 1)

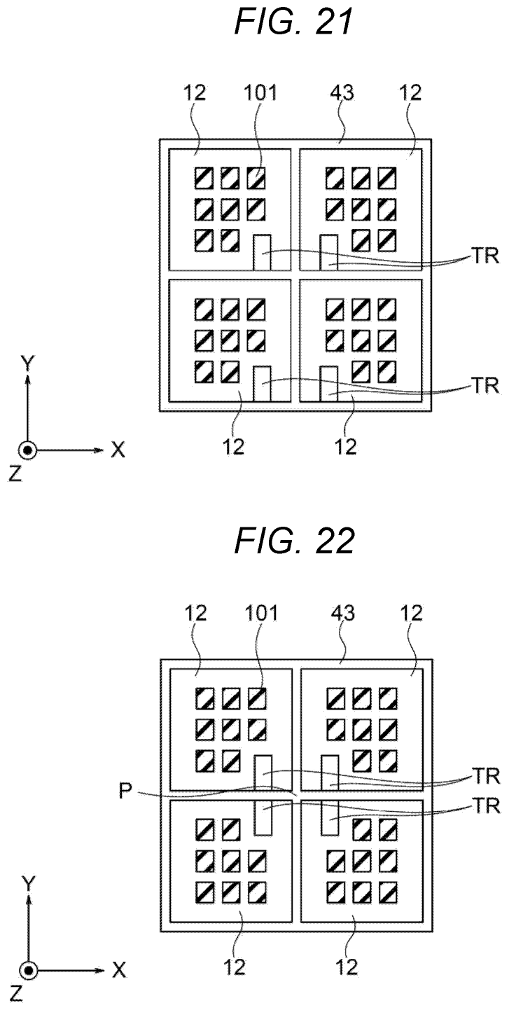

FIGS. 21 and 22 are plan views illustrating an example of a planar layout of first uneven structures 101 and transfer transistors TR according to Modification 1. FIGS. 21 and 22 illustrate the arrangement of the first uneven structures 101 and the transfer transistors TR in plan view as viewed from the light incident direction (Z direction). Furthermore, four pixels 12 illustrated in FIGS. 21 and 22 are pixels sharing a readout circuit 22.

The transfer transistors TR may be arranged at substantially the same position in the pixels 12 as illustrated in FIG. 8. However, the transfer transistors TR may be arranged as illustrated in FIG. 21 or 22 in consideration of optical symmetry or ease of wiring.

For example, in FIG. 21, the transfer transistors TR are arranged at positions symmetric with respect to an element isolation part 43 (Y axis) between the pixels 12 adjacent in the X direction. In FIG. 22, the transfer transistors TR are arranged in positions symmetric with respect to the element isolation part 43 (Y axis) between the pixels 12 adjacent in the X direction, and also symmetric with respect to the element isolation part 43 (X axis) between the pixels 12 adjacent in the Y direction. The transfer transistors TR are provided so as to be close to a vertex P shared by the four pixels 12, and are arranged so as to be symmetric with respect to the vertex P.

Comparing the arrangements in FIGS. 8, 21, and 22, the optical symmetry in the four pixels 12 is the best in the arrangement in FIG. 8, and is lower in the order of FIGS. 21 and 22. On the other hand, the ease of drawing the wiring from the transfer transistor TR is the easiest in the arrangement of FIG. 22, and becomes difficult in the order of FIGS. 21 and 8. This is because, in the arrangement of FIG. 22, the transfer transistors TR of the four pixels 12 are collectively provided at one vertex P.

Modification 1 may be applied to any embodiment of the present specification.

(Modification 2)

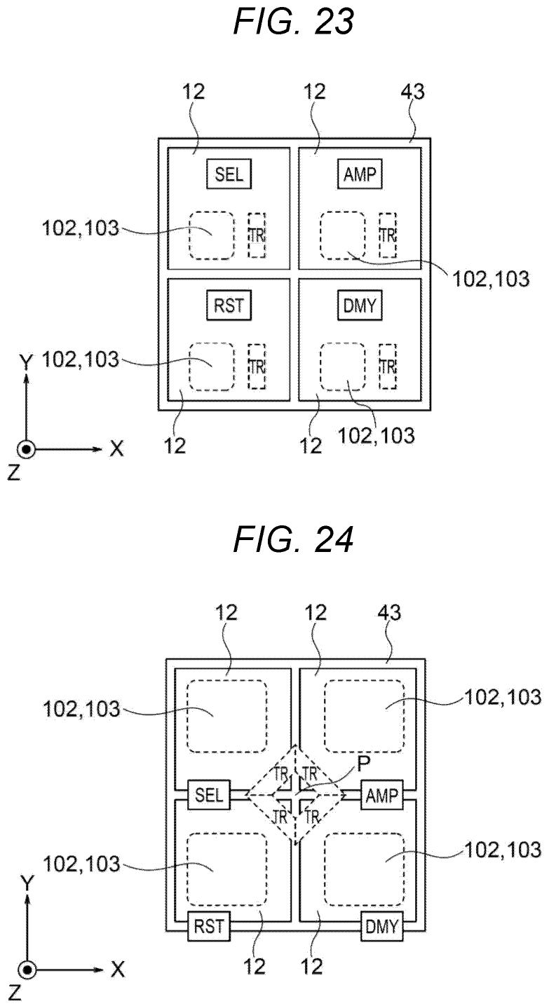

FIGS. 23 and 24 are plan views illustrating arrangements of first and second uneven structures 101 and 102, transfer transistor TR, and a readout circuit 22 according to Modification 2. The first and second uneven structures 101 and 102, the transfer transistor TR, and the element isolation part 43 are formed on a first substrate 10. Pixel transistors (AMP, SEL, RST, DMY) forming the readout circuit 22 are formed on a second substrate 20. Note that four pixels illustrated in FIGS. 23 and 24 are pixels sharing the readout circuit 22.

The pixel transistors of the readout circuit 22 may be arranged in the pixels 12 as illustrated in FIGS. 17 and 18. However, in consideration of the optical symmetry, the pixel transistors of the readout circuit 22 may be arranged as illustrated in FIG. 23 or 24.

For example, in the arrangement of the pixel transistors in FIG. 23, the orientation of the pixel transistors is rotated by 90 degrees in the X direction and the Y direction with respect to that in FIG. 17. Other arrangements in FIG. 23 may be the same as the arrangements in FIG. 17. Even in the arrangement of FIG. 23, optical symmetry similar to that of the arrangement of FIG. 17 can be obtained.

The pixel transistors of FIG. 24 overlap the element isolation part 43 in plan view as viewed from the Z direction, but the positions thereof are different from the arrangement of FIG. 18. In FIG. 24, the amplification transistor AMP and the selection transistor SEL are arranged so as to overlap the element isolation parts 43 on both sides of the transfer transistor TR. The reset transistor RST and the dummy transistor DMY are provided on opposite sides of the pixel 12 with respect to the selection transistor SEL and the amplification transistor AMP, respectively. Even in the arrangement of FIG. 24, effects similar to those in the arrangement of FIG. 18 can be obtained.

Modification 2 may be applied to any embodiment of the present specification.

(Modification 3)

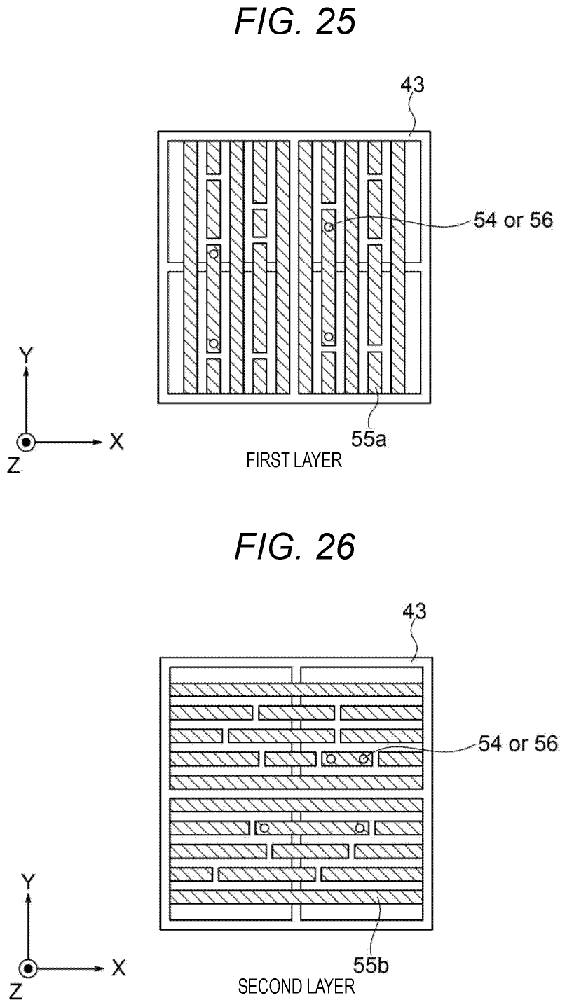

FIGS. 25 and 26 are plan views illustrating a configuration example of a wiring layer 55 of a second substrate 20 according to Modification 3. The wiring layer 55 of the second substrate 20 includes a plurality of wiring layers 55a and 55b. FIG. 25 illustrates a layout of wiring layers (first wiring layers) 55a of a first layer in plan view as viewed from the Z direction. FIG. 26 illustrates a layout of wiring layers (second wiring layers) 55b of a second layer in plan view as viewed from the Z direction. The wiring layers 55a and 55b are stacked in the Z direction, and an interlayer insulating film 51 is provided therebetween. Note that in the plan view, an element isolation part 43 corresponding to four pixels 12 sharing a readout circuit 22 is illustrated for convenience.

The plurality of wiring layers 55a extends in the Y direction and are arranged in the X direction. That is, the plurality of wiring layers 55a is arranged in a stripe shape.

The plurality of wiring layers 55b extends in the X direction and are arranged in the Y direction. That is, the plurality of wiring layers 55b is arranged in a stripe shape so as to be substantially orthogonal to the wiring layer 55a.

By arranging the wiring layers 55a and 55b in a stripe shape, even if light incident on the first substrate 10 leaks to the second substrate 20, the light can be kept from passing further from the second substrate 20 to the third substrate 30. That is, the wiring layers 55a and 55b have both a function as wiring and a function as a light shielding film. For the wiring layers 55a and 55b, for example, a metal material having a high light shielding property such as copper is used.

Furthermore, in plan view as viewed from the Z direction, the wiring layer 55a and the wiring layer 55b intersect each other so as to be substantially orthogonal to each other, whereby the wiring layer 55b can further shield light passing between the wiring layers 55a adjacent to each other. Therefore, by combining the wiring layer 55a and the wiring layer 55b, the light shielding property in the second substrate 20 is further improved. The pitch between the wirings of the wiring layers 55a and 55b is preferably narrow in consideration of the light shielding property.

The wiring layers 55a and 55b include wiring parts that are connected to electrode plugs 54 and 56 and are used as wiring, and dummy parts that are not actually used as wiring. The wiring part and the dummy part are electrically separated from each other. As a result, erroneous connection of the wiring part is curbed, and the parasitic capacitance of the wiring part is not increased. Furthermore, the light shielding property can be maintained by leaving the dummy part.

Modification 3 may be applied to any embodiment of the present specification.

### Fifth Embodiment

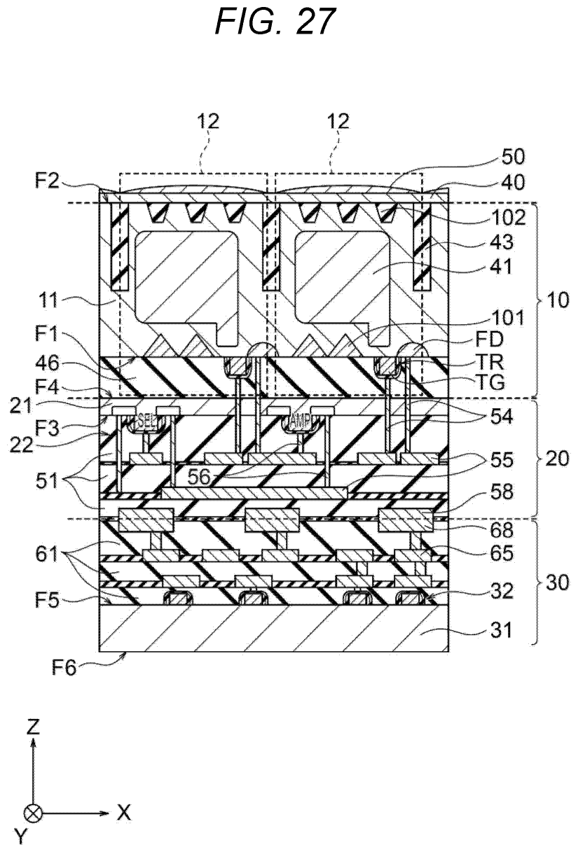

FIG. 27 is a cross-sectional view illustrating a configuration example of an imaging device 1 according to a fifth embodiment. In the fifth embodiment, a first uneven structure 101 is formed in a substantially quadrangular pyramid shape, and a second uneven structure 102 is formed in a substantially quadrangular frustum shape. Other configurations of the fifth embodiment may be similar to the corresponding configurations of the first embodiment. As a result, the fifth embodiment can obtain effects similar to those of the first embodiment.

### Sixth Embodiment

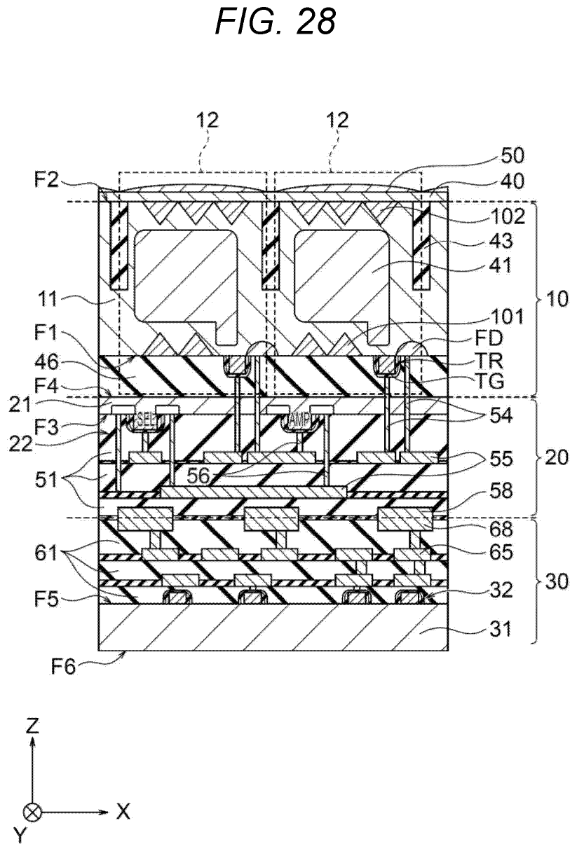

FIG. 28 is a cross-sectional view illustrating a configuration example of an imaging device 1 according to a sixth embodiment. In the sixth embodiment, both first and second uneven structures 101 and 102 are formed in a substantially quadrangular pyramid shape. Other configurations of the sixth embodiment may be similar to the corresponding configurations of the first embodiment. As a result, the sixth embodiment can obtain effects similar to those of the first embodiment.

### Seventh Embodiment

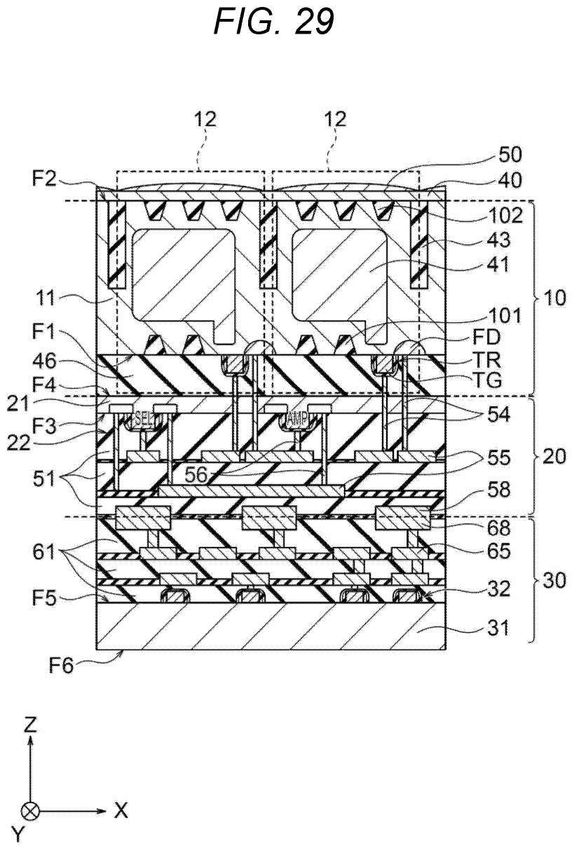

FIG. 29 is a cross-sectional view illustrating a configuration example of an imaging device 1 according to a seventh embodiment. In the seventh embodiment, both the first and second uneven structures 101 and 102 are formed in a substantially quadrangular frustum shape. Other configurations of the seventh embodiment may be similar to the corresponding configurations of the first embodiment. As a result, the seventh embodiment can obtain effects similar to those of the first embodiment.

### Eighth Embodiment

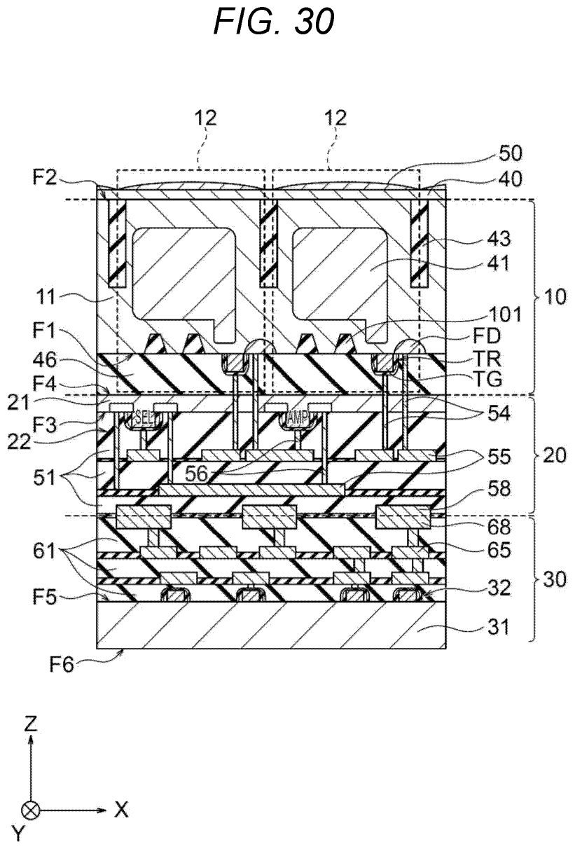

FIG. 30 is a cross-sectional view illustrating a configuration example of an imaging device 1 according to an eighth embodiment. In the eighth embodiment, a first uneven structure 101 is provided, but a second uneven structure 102 is omitted. The first uneven structure 101 is formed in a substantially quadrangular frustum shape. The first uneven structure 101 can reflect incident light to a PD 41 and can curb leakage of light to a second substrate 20 and a third substrate 30. As described above, the effect of improving the photoelectric conversion efficiency can be obtained to some extent only by providing the first uneven structure 101. At the same time, effects of curbing dark current and noise in a readout circuit 22 of the second substrate 20 and curbing malfunction of a logic circuit 32 of the third substrate 30 can be obtained. Furthermore, since there is no reflected light from the second uneven structure 102, dark current and noise in the readout circuit 22 can be curbed even more, and malfunction of the logic circuit 32 can be curbed even more.

Other configurations of the eighth embodiment may be similar to the corresponding configurations of the first embodiment. As a result, the eighth embodiment can obtain effects similar to those of the first embodiment.

### Ninth Embodiment

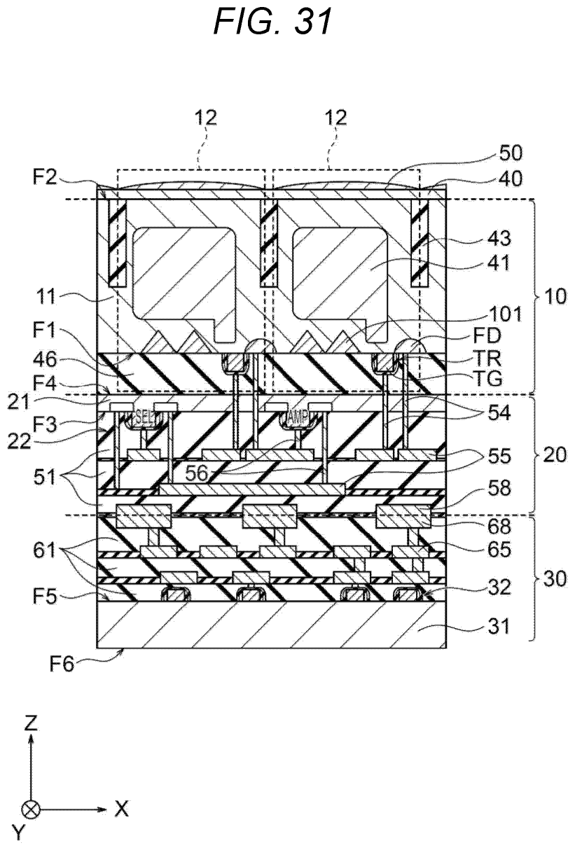

FIG. 31 is a cross-sectional view illustrating a configuration example of an imaging device 1 according to a ninth embodiment. The ninth embodiment is the same as the eighth embodiment in that a second uneven structure 102 is omitted. However, in the ninth embodiment, a first uneven structure 101 is formed in a substantially quadrangular pyramid shape. Other configurations of the ninth embodiment may be similar to the corresponding configurations of the eighth embodiment. As a result, the ninth embodiment can obtain effects similar to those of the eighth embodiment.

(Modification 4)

FIGS. 32 to 35 are plan views illustrating configuration examples of a first uneven structure 101 on a first surface F1 side. In FIGS. 32 to 35, the first uneven structure 101 is formed in a substantially quadrangular frustum shape as illustrated in FIG. 29. The first uneven structure 101 illustrated in FIG. 8 is formed in a dot shape and is arranged in a matrix shape.

On the other hand, the plurality of first uneven structures 101 illustrated in FIG. 32 extends in the Y direction and are arranged in the X direction. That is, the plurality of first uneven structures 101 is arranged in a vertical stripe shape.

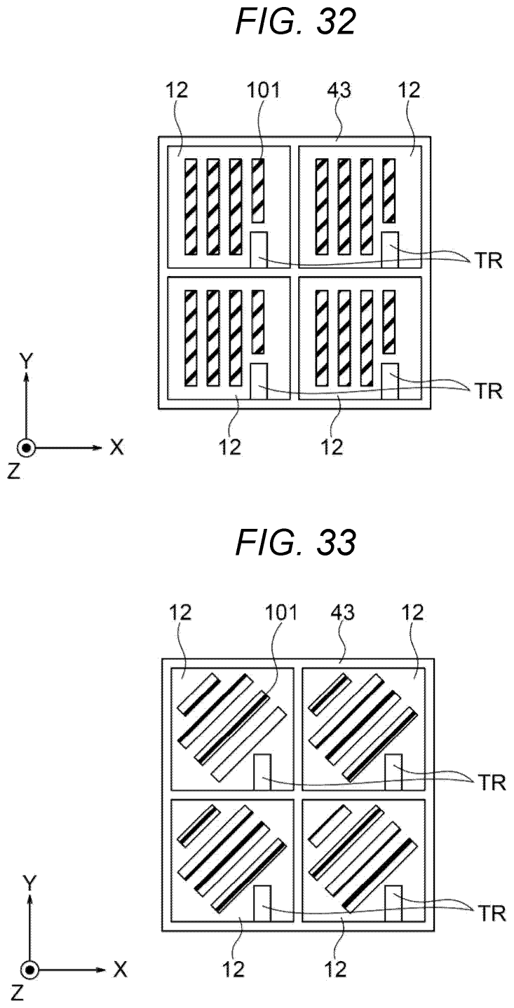

The plurality of first uneven structures 101 illustrated in FIG. 33 extends in a direction inclined with respect to the X and Y directions, and is arranged in a direction substantially orthogonal to the inclination direction. That is, the plurality of first uneven structures 101 is arranged in a stripe shape in a direction inclined with respect to the side of a pixel 12 or an element isolation part 43.

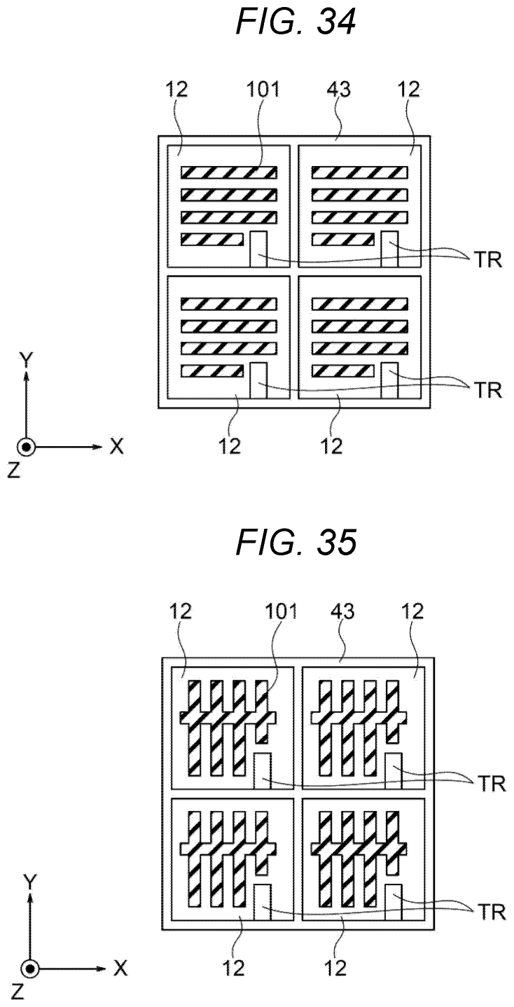

The plurality of first uneven structures 101 illustrated in FIG. 34 extends in the X direction and is arranged in the Y direction. That is, the plurality of first uneven structures 101 is arranged in a horizontal stripe shape.

The plurality of first uneven structures 101 illustrated in FIG. 35 is a combination of a vertical stripe structure and a horizontal stripe structure. That is, the plurality of first uneven structures 101 is arranged in a strip shape such that horizontal stripe structures overlap vertical stripe structures. Note that the plurality of first uneven structures 101 may be arranged in a strip shape such that vertical stripe structures overlap horizontal stripe structures.

The first uneven structure 101 is not limited thereto, and may have various structures. Modification 4 can be applied to any embodiment of the present specification.

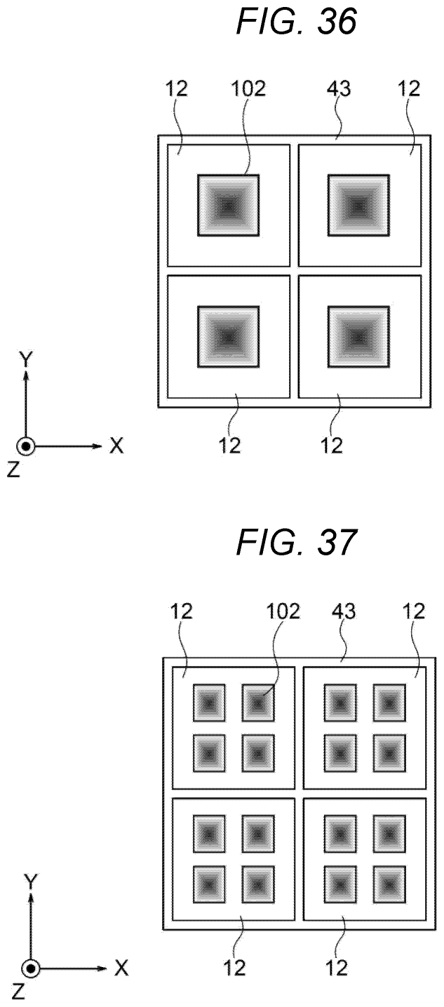

(Modification 5) FIGS. 36 to 41 are plan views illustrating configuration examples of a second uneven structure 102 on a second surface F2 side. In FIGS. 36 to 41, the second uneven structure 102 is formed in a substantially quadrangular frustum shape as illustrated in FIG. 29.

One second uneven structure 102 illustrated in FIG. 36 is provided for each pixel 12.

The second uneven structure 102 illustrated in FIG. 37 is formed in a dot shape, and is arranged in a matrix in the Y direction and the X direction.

The plurality of second uneven structures 102 illustrated in FIG. 38 extends in the Y direction and is arranged in the X direction. That is, the plurality of second uneven structures 102 is arranged in a vertical stripe shape.

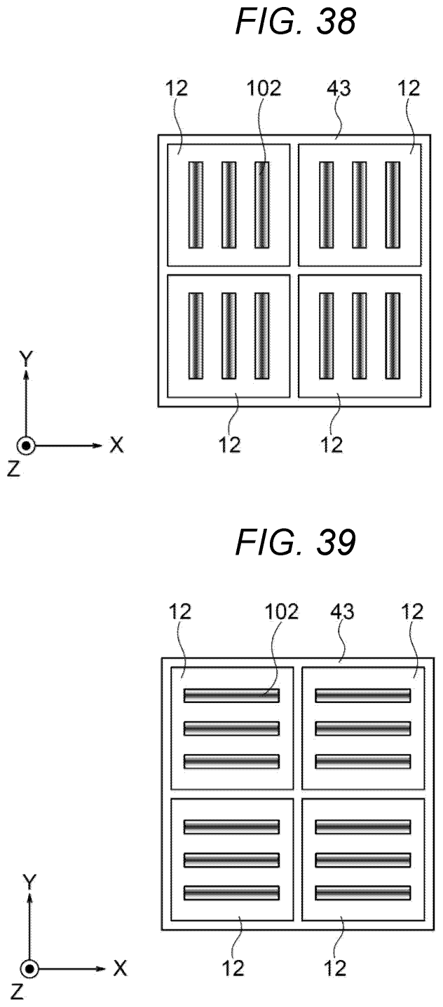

The plurality of second uneven structures 102 illustrated in FIG. 39 extends in the X direction and is arranged in the Y direction. That is, the plurality of second uneven structures 102 is arranged in a horizontal stripe shape.

The second uneven structure 102 illustrated in FIG. 40 is formed by intersecting a structure extending in the Y direction and a structure extending in the X direction so as to be substantially orthogonal to each other, and has a substantial cross shape.

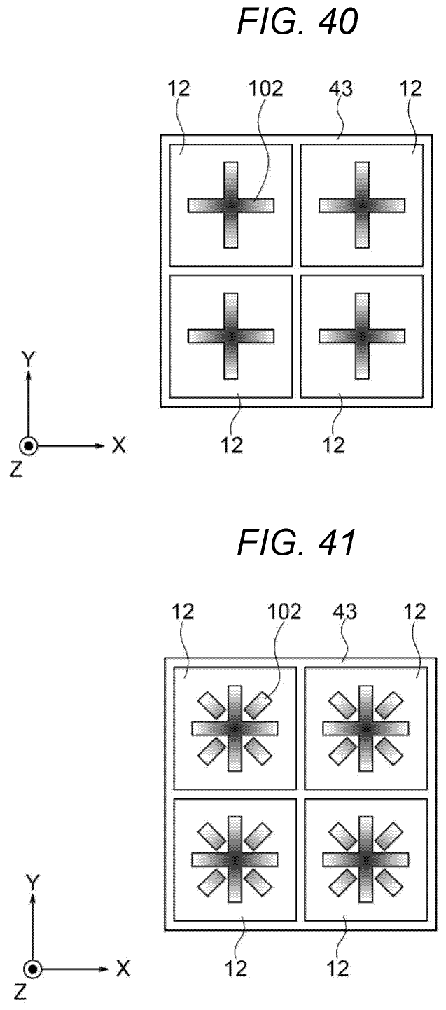

The second uneven structure 102 illustrated in FIG. 41 is a combination of structures extending in directions inclined with respect to the X and Y directions and the cross shape illustrated in FIG. 40. That is, the second uneven structure 102 may be configured in an asterisk shape.

The second uneven structure 102 is not limited thereto, and may have various structures. Modification 5 can be applied to any embodiment of the present specification.

(Modification 6)

FIGS. 42 to 46 are plan views illustrating configuration examples of the first or second uneven structure 101 or 102. In FIGS. 42 to 46, it is assumed that the first or second uneven structure 101 or 102 is formed in a substantially quadrangular pyramid as illustrated in FIG. 28. Hereinafter, the configuration of the second uneven structure 102 will be described. Since the configuration of the first uneven structure 101 can be the same as that of the second uneven structure 102, the description thereof will be omitted. Four second uneven structures 102 illustrated in FIG. 42 are provided for each pixel 12. The second uneven structure 102 is formed in a dot shape, and is arranged in a matrix in the Y direction and the X direction.

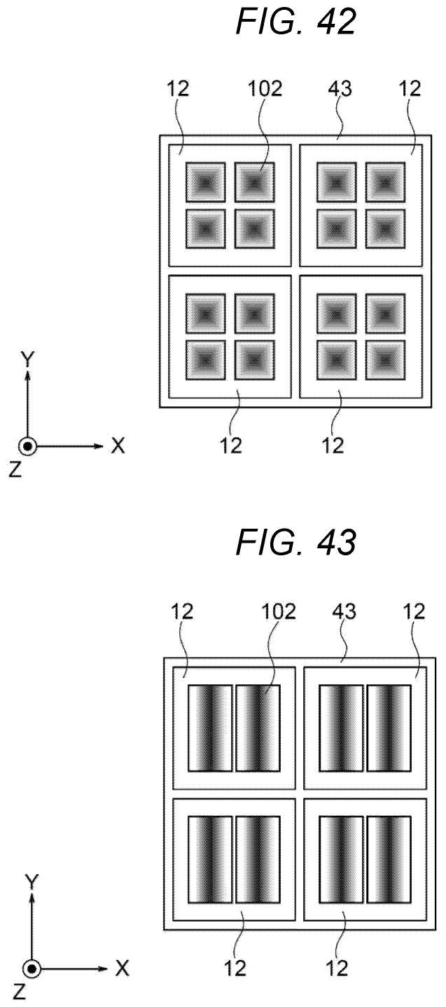

The plurality of second uneven structures 102 illustrated in FIG. 43 extends in the Y direction and is arranged in the X direction. That is, the plurality of second uneven structures 102 is arranged in a vertical stripe shape.

The plurality of second uneven structures 102 illustrated in FIG. 44 extends in a direction inclined with respect to the X and Y directions, and is arranged in a direction substantially orthogonal to the inclination direction. That is, the plurality of second uneven structures 102 is arranged in a stripe shape in a direction inclined with respect to the side of a pixel 12 or an element isolation part 43.

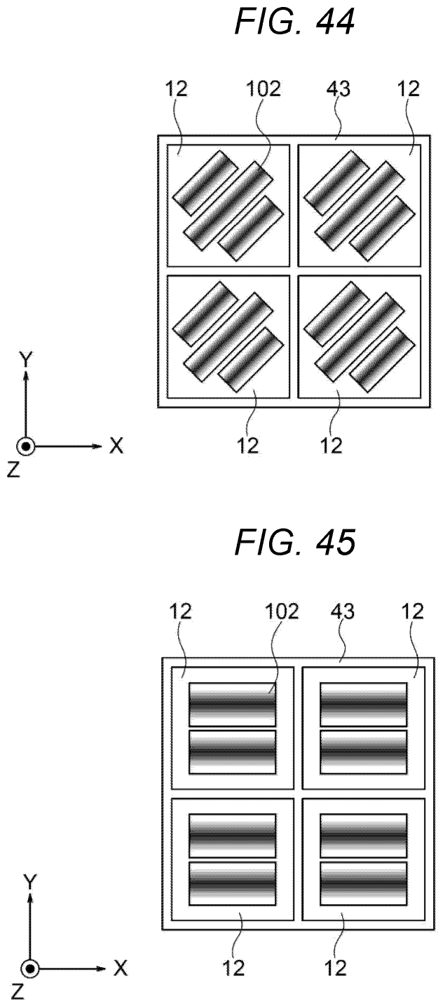

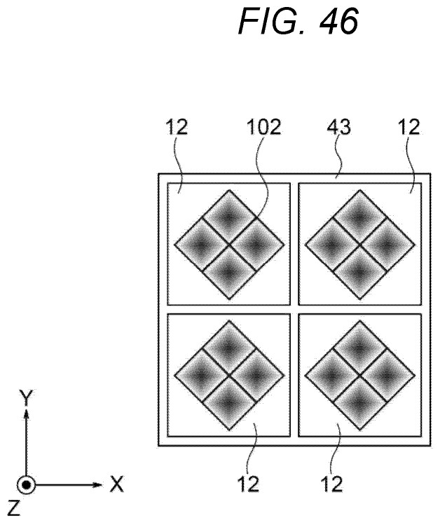

The plurality of second uneven structures 102 illustrated in FIG. 45 extends in the X direction and is arranged in the Y direction. That is, the plurality of second uneven structures 102 is arranged in a horizontal stripe shape.

Four second uneven structures 102 illustrated in FIG. 46 are provided for each pixel 12. The second uneven structure 102 is formed in a dot shape, and is arranged in a matrix in a direction inclined with respect to the Y direction and the X direction.

The first and second uneven structures 101 and 102 are not limited thereto, and may have various structures. Modification 6 can be applied to any embodiment of the present specification.

### Tenth Embodiment

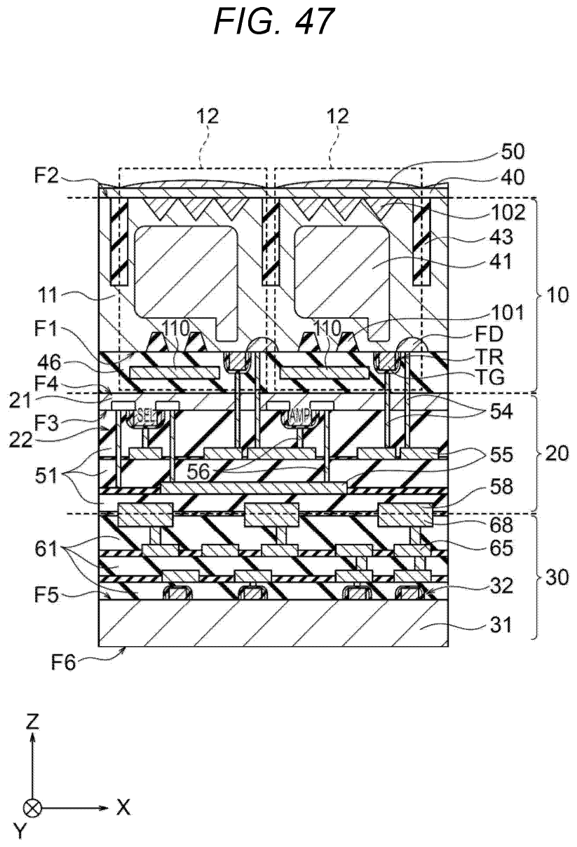

FIG. 47 is a cross-sectional view illustrating a configuration example of an imaging device 1 according to a tenth embodiment. In the tenth embodiment, a reflection member 110 is provided in an insulating layer 46 of a first substrate 10. The reflection member 110 is provided between a first uneven structure 101 of the first substrate 10 and a pixel transistor (AMP, SEL, RST) of a readout circuit 22 of a second substrate 20. The reflection member 110 has a function of curbing passage of light incident on a pixel 12 to the readout circuit 22 of the second substrate 10 and reflecting the light to a PD 41. As a result, photoelectric conversion efficiency in a pixel 12 can be improved, and dark current and noise in the readout circuit 22 can be curbed.

For example, a metal material such as copper, tungsten, or aluminum is used for the reflection member 110. The reflection member 110 may include the same material as wiring layers 55 and 65. Note that in the present embodiment, the reflection member 110 does not function as a wiring, but may function as a wiring.

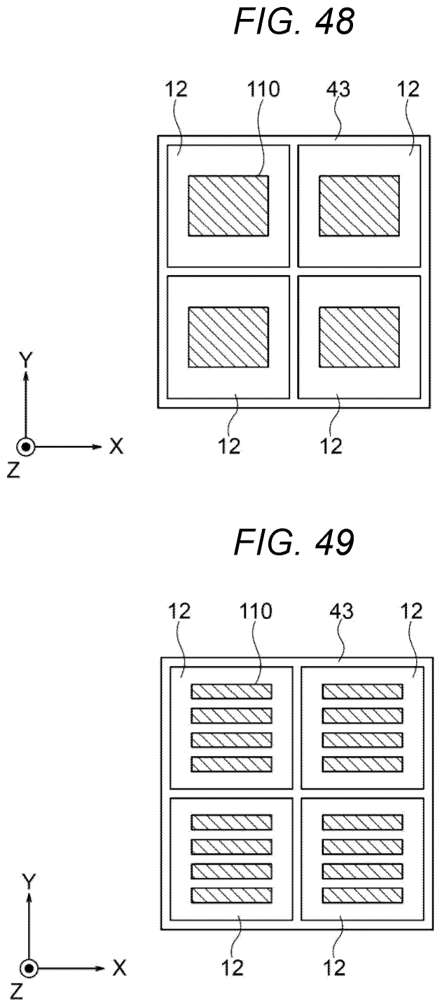

FIGS. 48 to 51 are plan views illustrating configuration examples of the reflection member 110. FIGS. 48 to 51 illustrate the configuration of the reflection member 110 in plan view as viewed from the Z direction. Note that in FIGS. 48 to 51, an element isolation part 43 corresponding to four pixels 12 sharing the readout circuit 22 are illustrated for convenience.

In FIG. 48, in plan view as viewed from the Z direction, the reflection member 110 is provided so as to overlap the entire first uneven structure 101 and/or the entire readout circuit 22. One reflection member 110 is provided for each pixel 12. As a result, the reflection member 110 can curb entry of incident light into the readout circuit 22 and reflect the light to the PD 41.

The reflection members 110 illustrated in FIG. 49 extend in the X direction and are arranged in the Y direction. That is, the plurality of reflection members 110 is arranged in a stripe shape.

The reflection members 110 illustrated in FIG. 50 extend in the Y direction and are arranged in the X direction. That is, the plurality of reflection members 110 is arranged in a stripe shape.

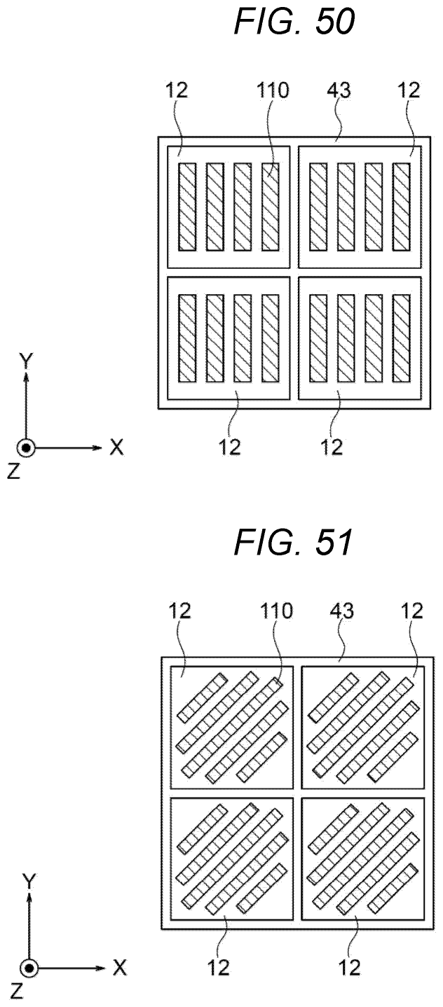

The reflection members 110 illustrated in FIG. 51 extend in a direction inclined with respect to the X and Y directions, and are arranged in a direction substantially orthogonal to the inclination direction. That is, the plurality of first uneven structures 101 is arranged in a stripe shape in a direction inclined with respect to the side of the pixel 12 or the element isolation part 43.

As described above, even when the reflection member 110 is formed in a stripe shape, it is possible to curb entry of incident light into the readout circuit 22 and reflect the light to the PD 41. The pitch between the adjacent reflection members 110 is preferably narrow in consideration of the reflectivity and the light shielding property.

### Eleventh Embodiment

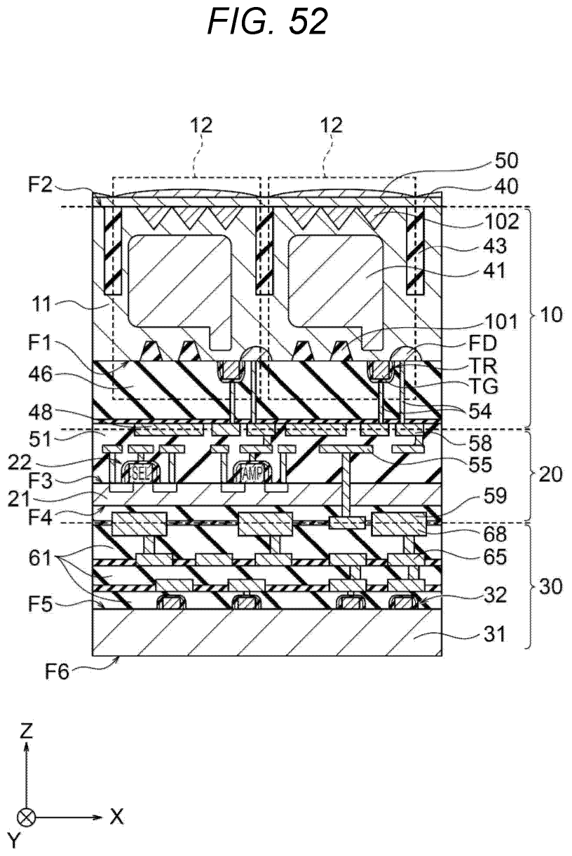

FIG. 52 is a cross-sectional view illustrating a configuration example of an imaging device 1 according to an eleventh embodiment. In the eleventh embodiment, a first substrate 10 and a second substrate 20 are bonded to each other by wiring. In addition, the vertical direction of the second substrate 20 is reversed from that of the second substrate 20 illustrated in FIG. 7. Therefore, the second substrate 20 is bonded to the first substrate 10 in a face-to-face manner, and bonded to a third substrate 30 in a back-to-face manner. By bonding an insulating layer 46 of the first substrate 10 and an interlayer insulating film 51 of the second substrate 20, a pad electrode 58 of the second substrate 20 is bonded to a pad electrode 48 of the first substrate 10 (Cu—Cu bonding). By bonding the insulating layer 46 of the second substrate 20 and the interlayer insulating film 51 of the second substrate 20, the pad electrode 58 of the second substrate 20 is bonded to the pad electrode 48 of the first substrate 10. In this manner, the wirings of the first substrate 10 and the second substrate 20 may be directly bonded (Cu—Cu bonding) without using an electrode plug 56 between the first substrate 10 and the second substrate 20.

Other configurations of the eleventh embodiment may be the same as those of the first embodiment. Therefore, the eleventh embodiment can also obtain the effect of the first embodiment. Furthermore, the eleventh embodiment may be combined with other embodiments.

In the above embodiment, the first and second uneven structures 101 and 102 have a substantially quadrangular pyramid shape or a substantially quadrangular frustum shape. However, the first and second uneven structures 101 and 102 are not limited thereto, and may be a substantially circular weight, a substantially circular weight base, a substantially triangular weight, a substantially triangular weight base, a substantially polygonal weight, or a substantially polygonal weight base. In this case, the first and second uneven structures 101 and 102 have substantially circular and substantially polygonal shapes in plan view as viewed from the Z direction. In a cross section perpendicular to a first surface F1, the first and second uneven structures 101 and 102 have substantially triangular, substantially trapezoidal, and substantially quadrangular (for example, substantially rectangular) shapes.

Furthermore, the first and second uneven structures 101 and 102 may be substantially cylindrical or substantially prismatic. In this case, the first and second uneven structures 101 and 102 have substantially circular and substantially polygonal shapes in plan view as viewed from the Z direction. In a cross section perpendicular to the first surface F1, the first and second uneven structures 101 and 102 have a substantially quadrangular (for example, substantially rectangular) shape.

The shapes and planar layouts of the first and second uneven structures 101 and 102 only need to be selected so as to maximize the optical diffraction effect.

The present technology can be applied to various electric devices (for example, a camera, a smartphone, an automobile, or the like) having an imaging function.

<Example of Application to Mobile Body>

The technology according to the present disclosure (the present technology) can be applied to various products. For example, the technology according to the present disclosure may be implemented as a device to be mounted on any one of the following types of mobile objects: cars, electric cars, hybrid electric cars, motorcycles, bicycles, personal mobilities, airplanes, drones, ships, robots, and the like.

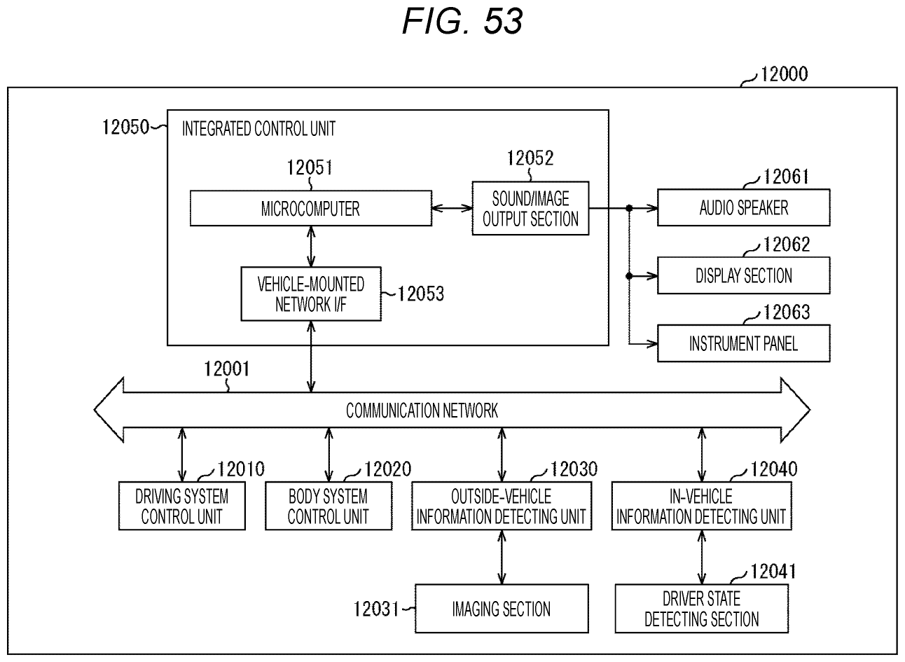

FIG. 53 is a block diagram illustrating a schematic configuration example of a vehicle control system which is an example of a mobile body control system to which the technology of the present disclosure can be applied.

The vehicle control system 12000 includes a plurality of electronic control units connected to each other via a communication network 12001. In the example illustrated in FIG. 53, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 53, an audio speaker 12061, a display section 12062, and an instrument panel 12063 are illustrated as the output device. The display section 12062 may, for example, include at least one of an on-board display and a head-up display.

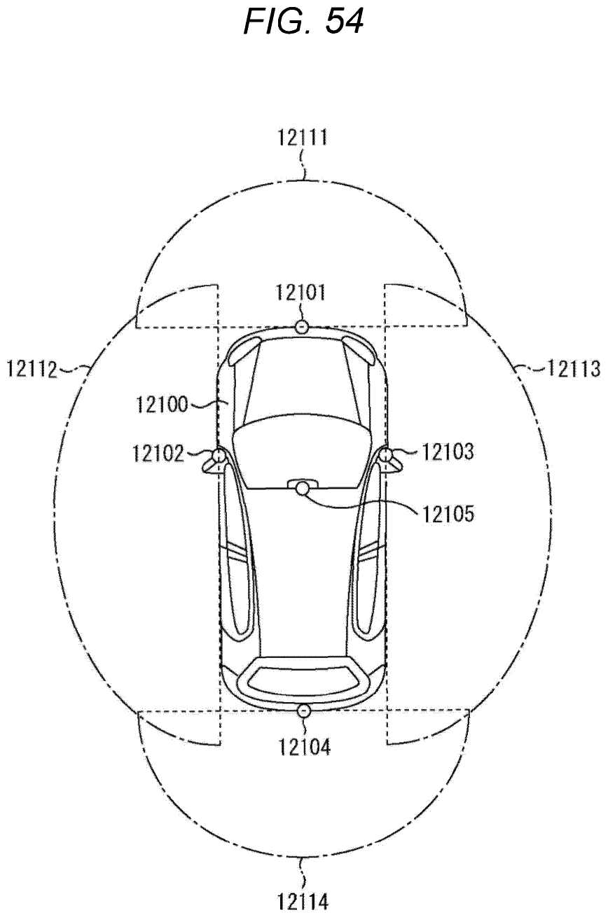

FIG. 54 is a diagram illustrating an example of the installation position of the imaging section 12031.

In FIG. 54, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Note that FIG. 54 illustrates an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure may be applied to the imaging section 12031, for example, out of the configurations described above.

Note that the present technology can also employ the following configurations.

(1)

A solid-state imaging device including
a first substrate including a first semiconductor substrate having a first surface and a second surface that is opposite to the first surface and on which light is incident, a plurality of pixels that is provided in the first semiconductor substrate and performs photoelectric conversion, and a first uneven structure that is provided on the first surface side of the first semiconductor substrate and includes a material different from a material of the first semiconductor substrate, and
a second substrate including a pixel transistor that is bonded to the first substrate on the first surface side and outputs a pixel signal based on electric charge output from the plurality of pixels.

(2)

The solid-state imaging device according to (1) further including a second uneven structure provided on the second surface side of the first semiconductor substrate and including a material different from a material of the first semiconductor substrate.

(3)

The solid-state imaging device according to (1) or (2), in which
the pixel includes a photoelectric conversion element, a transfer transistor electrically connected to the photoelectric conversion element, and a floating diffusion that temporarily holds electric charge output from the photoelectric conversion element via the transfer transistor, and
the pixel transistor includes an amplification transistor that generates, as the pixel signal, a voltage signal according to electric charge held in the floating diffusion, and a selection transistor that controls an output timing of the pixel signal from the amplification transistor.

(4)

The solid-state imaging device according to any one of (1) to (3) further including an element isolation structure provided between the pixels adjacent to each other in the first semiconductor substrate.

(5)

The solid-state imaging device according to (3), in which the transfer transistor is arranged at substantially the same position in each of the plurality of pixels in plan view as viewed from an incident direction of the light.

(6)

The solid-state imaging device according to (3), in which the transfer transistor includes an embedded gate electrode embedded in the first semiconductor substrate.

(7)

The solid-state imaging device according to (6), in which a first insulating film provided on a part of a side surface of the embedded gate electrode is thinner in film thickness than a second insulating film provided on another part of the side surface of the gate electrode.

(8)

The solid-state imaging device according to (4), in which at least a part of the pixel transistor is provided below the element isolation structure.

(9)

The solid-state imaging device according to (4), in which at least a part of the pixel transistor overlaps the element isolation structure in plan view as viewed from an incident direction of the light.

(10)

The solid-state imaging device according to any one of (1) to (9), in which a first wiring layer of the second substrate includes a plurality of first wirings extending in a first direction and arranged in a second direction orthogonal to the first direction in plan view as viewed from an incident direction of the light.

(11)

The solid-state imaging device according to (2), in which the first or second uneven structure has a substantially triangular, substantially trapezoidal, or substantially rectangular shape in a cross section perpendicular to the first surface.

(12)

The solid-state imaging device according to (11), in which the first or second uneven structure has a shape of a substantially quadrangular pyramid, a substantially truncated cone, a substantially truncated pyramid, a substantial cylinder, or a substantial prism.

(13)

The solid-state imaging device according to (2), in which a plurality of the first or second uneven structures is arranged in a matrix in a first direction and a second direction orthogonal to the first direction in plan view as viewed from an incident direction of the light.

(14)

The solid-state imaging device according to (2), in which a plurality of the first or second uneven structures extends in a first direction, is arranged in a second direction orthogonal to the first direction, and is formed in a stripe shape in plan view as viewed from an incident direction of the light.

(15)

The solid-state imaging device according to (2), in which the first or second uneven structure has a cross shape extending in a first direction and a second direction orthogonal to the first direction in plan view as viewed from an incident direction of the light.

(16)

The solid-state imaging device according to any one of (1) to (15) further including a reflection member provided between the first uneven structure and the second substrate.

(17)

The solid-state imaging device according to any one of (1) to (16) further including an electrode plug provided between the first substrate and the second substrate.

(18)

The solid-state imaging device according to any one of (1) to (16), in which a wiring of the first substrate and a wiring of the second substrate are bonded by bonding the first substrate and the second substrate.

(19)

The solid-state imaging device according to any one of (1) to (16) further including a third substrate bonded to the second substrate and including a logic circuit that processes the pixel signal.

(20)

An electronic device including a solid-state imaging device including a first substrate including a first semiconductor substrate having a first surface and a second surface that is opposite to the first surface and on which light is incident, a plurality of pixels that is provided in the first semiconductor substrate and performs photoelectric conversion, and a first uneven structure that is provided on the first surface side of the first semiconductor substrate and includes a material different from a material of the first semiconductor substrate, and a second substrate including a pixel transistor that is bonded to the first substrate on the first surface side and outputs a pixel signal based on electric charge output from the plurality of pixels.

Note that the present disclosure is not limited to the above-described embodiments, and various modifications can be made without departing from the gist of the present disclosure. Furthermore, the effects described in the present specification are merely examples and are not limited, and other effects may be provided.

### REFERENCE SIGNS LIST

1 Imaging device
10 First substrate
20 Second substrate
30 Third substrate
11, 21, 31 Semiconductor substrate
12 Pixel
22 Readout circuit
32 Logic circuit
41 PD
43 Element isolation part
55, 65 Wiring layer
58, 68 Pad electrode
TR Transfer transistor
FD Floating diffusion
101 First uneven structure
102 Second uneven structure

1. A solid-state imaging device comprising
a first substrate including a first semiconductor substrate having a first surface and a second surface that is opposite to the first surface and on which light is incident, a plurality of pixels that is provided in the first semiconductor substrate and performs photoelectric conversion, and a first uneven structure that is provided on the first surface side of the first semiconductor substrate and includes a material different from a material of the first semiconductor substrate, and
a second substrate including a pixel transistor that is bonded to the first substrate on the first surface side and outputs a pixel signal based on electric charge output from the plurality of pixels.

2. The solid-state imaging device according to claim 1 further comprising a second uneven structure provided on the second surface side of the first semiconductor substrate and including a material different from a material of the first semiconductor substrate.

3. The solid-state imaging device according to claim 1, wherein
the pixel includes a photoelectric conversion element, a transfer transistor electrically connected to the photoelectric conversion element, and a floating diffusion that temporarily holds electric charge output from the photoelectric conversion element via the transfer transistor, and
the pixel transistor includes an amplification transistor that generates, as the pixel signal, a voltage signal according to electric charge held in the floating diffusion, and a selection transistor that controls an output timing of the pixel signal from the amplification transistor.

4. The solid-state imaging device according to claim 1 further comprising an element isolation structure provided between the pixels adjacent to each other in the first semiconductor substrate.

5. The solid-state imaging device according to claim 3, wherein the transfer transistor is arranged at substantially the same position in each of the plurality of pixels in plan view as viewed from an incident direction of the light.

6. The solid-state imaging device according to claim 3, wherein the transfer transistor includes an embedded gate electrode embedded in the first semiconductor substrate.

7. The solid-state imaging device according to claim 6, wherein a first insulating film provided on a part of a side surface of the embedded gate electrode is thinner in film thickness than a second insulating film provided on another part of the side surface of the gate electrode.

8. The solid-state imaging device according to claim 4, wherein at least a part of the pixel transistor is provided below the element isolation structure.

9. The solid-state imaging device according to claim 4, wherein at least a part of the pixel transistor overlaps the element isolation structure in plan view as viewed from an incident direction of the light.

10. The solid-state imaging device according to claim 1, wherein a first wiring layer of the second substrate includes a plurality of first wirings extending in a first direction and arranged in a second direction orthogonal to the first direction in plan view as viewed from an incident direction of the light.

11. The solid-state imaging device according to claim 2, wherein the first or second uneven structure has a substantially triangular, substantially trapezoidal, or substantially rectangular shape in a cross section perpendicular to the first surface.

12. The solid-state imaging device according to claim 11, wherein the first or second uneven structure has a shape of a substantially quadrangular pyramid, a substantially truncated cone, a substantially truncated pyramid, a substantial cylinder, or a substantial prism.

13. The solid-state imaging device according to claim 2, wherein a plurality of the first or second uneven structures is arranged in a matrix in a first direction and a second direction orthogonal to the first direction in plan view as viewed from an incident direction of the light.

14. The solid-state imaging device according to claim 2, wherein a plurality of the first or second uneven structures extends in a first direction, is arranged in a second direction orthogonal to the first direction, and is formed in a stripe shape in plan view as viewed from an incident direction of the light.

15. The solid-state imaging device according to claim 2, wherein the first or second uneven structure has a cross shape extending in a first direction and a second direction orthogonal to the first direction in plan view as viewed from an incident direction of the light.

16. The solid-state imaging device according to claim 1 further comprising a reflection member provided between the first uneven structure and the second substrate.

17. The solid-state imaging device according to claim 1 further comprising an electrode plug provided between the first substrate and the second substrate.

18. The solid-state imaging device according to claim 1, wherein a wiring of the first substrate and a wiring of the second substrate are bonded by bonding the first substrate and the second substrate.

19. The solid-state imaging device according to claim 1 further comprising a third substrate bonded to the second substrate and including a logic circuit that processes the pixel signal.

20. An electronic device comprising a solid-state imaging device including
a first substrate including a first semiconductor substrate having a first surface and a second surface that is opposite to the first surface and on which light is incident, a plurality of pixels that is provided in the first semiconductor substrate and performs photoelectric conversion, and a first uneven structure that is provided on the first surface side of the first semiconductor substrate and includes a material different from a material of the first semiconductor substrate, and
a second substrate including a pixel transistor that is bonded to the first substrate on the first surface side and outputs a pixel signal based on electric charge output from the plurality of pixels.
